(19) United States
(12) Patent Application Publication
(10) Pub. No.: US 2018/0145703 A1
(43) Pub. Date: May 24, 2018

(54) TECHNIQUES FOR USING A CYCLIC REDUNDANCY CHECK IN CONJUNCTION WITH A LOW-DENSITY PARITY-CHECK ENCODING SCHEME

(71) Applicant: QUALCOMM Incorporated, San Diego, CA (US)

(72) Inventors: Wenjun Li, Basking Ridge, NJ (US); Tao Luo, San Diego, CA (US)

(21) Appl. No.: 15/703,862

(22) Filed: Sep. 13, 2017

Related U.S. Application Data
(60) Provisional application No. 62/426,103, filed on Nov. 23, 2016.

(51) Int. Cl. H03M 13/09; H03M 13/11

(52) U.S. Cl. CPC H03M 13/095; H04L 1/0016; H03M 13/1102

(57) ABSTRACT

Techniques are described for wireless communication at a wireless device. One method includes receiving a control channel and a data channel over a radio frequency spectrum, decoding the control channel, and decoding a packet received over the data channel. The control channel indicates a parameter of a codeblock group (CBG). The parameter of the CBG may indicate at least one of a number of codeblocks (CBs) associated with the CBG, a CBG size, or a combination thereof. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may be encoded based at least in part on a low-density parity-check (LDPC) encoding scheme.

### CROSS REFERENCES

The present application for patent claims the benefit of and priority to U.S. Provisional Patent Application No. 62/426,103 by LI, et al., entitled “TECHNIQUES FOR USING A CODEBLOCK GROUP-LEVEL CYCLIC REDUNDANCY CHECK IN CONJUNCTION WITH A LOW-DENSITY PARITY-CHECK ENCODING SCHEME,” filed Nov. 23, 2016, which is incorporated by reference in its entirety herein and assigned to the assignee hereof.

### BACKGROUND

### Field of the Disclosure

The present disclosure, for example, relates to wireless communication systems, and more particularly to techniques for using a cyclic redundancy check (CRC) in conjunction with a low-density parity-check (LDPC) encoding scheme.

### Description of Related Art

Wireless multiple-access technologies have been adopted in various telecommunication standards to provide a common protocol that enables different wireless devices to communicate on a municipal, national, regional, and even global level. An example telecommunication standard is Long Term Evolution (LTE). LTE is designed to improve spectral efficiency, lower costs, improve services, make use of new spectrum, and better integrate with other open standards. LTE may use orthogonal frequency-division multiple access (OFDMA) on a downlink (DL), single-carrier frequency division multiple access (SC-FDMA) on an uplink (UL), and multiple-input multiple-output (MIMO) antenna technology.

A wireless multiple-access communication system may include a number of network access devices, each simultaneously supporting communication for multiple communication devices, otherwise known as user equipment (UEs). In a LTE or LTE-Advanced (LTE-A) network, a network access device may take the form of a base station, with a set of one or more base stations defining an eNodeB (eNB). In a next generation, 5G, or new radio (NR) network, a network access device may take the form of a smart radio head (RH) or access node controller (ANC), with a set of smart radio heads in communication with an ANC defining one potential example of a gNodeB (gNB). A network access device may communicate with a set of UEs on a DL (e.g., for transmissions from a base station or smart radio head to a UE) and a UL (e.g., for transmissions from a UE to a network access device).

The successful transmission and decode of packets transmitted in a wireless multiple-access communication system may be managed using error detection mechanisms such as parity checks, CRCs, and acknowledgement/non-acknowledgement (ACK/NACK) feedback.

### SUMMARY

The present disclosure describes techniques for using a CRC in conjunction with a LDPC encoding scheme. By way of example, various of the described techniques pertain to determining when to include CBG-level CRCs for a packet, determining that CBG-level CRCs have been included in a packet, determining a parameter of a CBG, indicating a parameter of a CBG, or transmitting/receiving CBG-level ACK/NACK feedback.

A method of wireless communication is described. The method may include receiving a control channel and a data channel over a radio frequency spectrum, decoding the control channel, the control channel indicating a parameter of a codeblock group (CBG), the parameter of the CBG indicating at least one of a number of codeblocks (CBs) associated with the CBG, a CBG size, or a combination thereof, and decoding a packet received over the data channel, the packet including a set of CBGs, wherein each CBG of the set of CBGs is associated with a set of encoded CBs, and each encoded CB was encoded based at least in part on a low-density parity-check (LDPC) encoding scheme.

An apparatus for wireless communication is described. The apparatus may include means for receiving a control channel and a data channel over a radio frequency spectrum, means for decoding the control channel, the control channel indicating a parameter of a codeblock group (CBG), the parameter of the CBG indicating at least one of a number of codeblocks (CBs) associated with the CBG, a CBG size, or a combination thereof, and means for decoding a packet received over the data channel, the packet including a set of CBGs, wherein each CBG of the set of CBGs is associated with a set of encoded CBs, and each encoded CB was encoded based at least in part on a low-density parity-check (LDPC) encoding scheme.

Another apparatus for wireless communication is described. The apparatus may include a transceiver, a processor, memory in electronic communication with the processor, and instructions stored in the memory. The instructions may be operable to cause the processor to implement a wireless communications manager configured to receive, via the transceiver, a control channel and a data channel over a radio frequency spectrum, decode the control channel, the control channel indicating a parameter of a codeblock group (CBG), the parameter of the CBG indicating at least one of a number of codeblocks (CBs) associated with the CBG, a CBG size, or a combination thereof, and decode a packet received over the data channel, the packet including a set of CBGs, wherein each CBG of the set of CBGs is associated with a set of encoded CBs, and each encoded CB was encoded based at least in part on a low-density parity-check (LDPC) encoding scheme.

A non-transitory computer readable medium for wireless communication is described. The non-transitory computer-readable medium may include instructions operable to cause a processor to receive, via a transceiver, a control channel and a data channel over a radio frequency spectrum, decode the control channel, the control channel indicating a parameter of a codeblock group (CBG), the parameter of the CBG indicating at least one of a number of codeblocks (CBs) associated with the CBG, a CBG size, or a combination thereof, and decode a packet received over the data channel, the packet including a set of CBGs, wherein each CBG of the set of CBGs is associated with a set of encoded CBs, and each encoded CB was encoded based at least in part on a low-density parity-check (LDPC) encoding scheme.

In some examples of the method, apparatus, and non-transitory computer-readable medium described above, each CBG of the set of CBGs may be associated with a CBG level cyclic redundancy check (CRC) based at least in part on the parameter of the CBG.

Some examples of the method, apparatus, and non-transitory computer-readable medium described above may further include processes, features, means, or instructions for prior to decoding the control channel, decoding a transmission received over the radio frequency spectrum based at least in part on a default value of the parameter of the CBG.

Some examples of the method, apparatus, and non-transitory computer-readable medium described above may further include processes, features, means, or instructions for obtaining the default value of the parameter of the CBG from a broadcast channel received over the radio frequency spectrum, or from configuration information stored at the wireless device.

In some examples of the method, apparatus, and non-transitory computer-readable medium described above, the control channel indicates the parameter of the CBG by indicating a modification to the default value of the parameter of the CBG.

Some examples of the method, apparatus, and non-transitory computer-readable medium described above may further include processes, features, means, or instructions for decoding each CB in a set of encoded CBs based at least in part on the LDPC encoding scheme. Some examples of the method, apparatus, and non-transitory computer-readable medium described above may further include processes, features, means, or instructions for determining whether to transmit acknowledgement/non-acknowledgement (ACK/NACK) feedback for the set of decoded CBs.

Some examples of the method, apparatus, and non-transitory computer-readable medium described above may further include processes, features, means, or instructions for extracting from the set of decoded CBs, based at least in part on the parameter of the CBG, a first CBG-level CRC. Some examples of the method, apparatus, and non-transitory computer-readable medium described above may further include processes, features, means, or instructions for verifying the first CBG-level CRC. Some examples of the method, apparatus, and non-transitory computer-readable medium described above may further include processes, features, means, or instructions for determining, based at least in part on the verification of the first CBG-level CRC, whether to continue decoding the packet, whether to transmit acknowledgement/non-acknowledgement (ACK/NACK) feedback for the set of decoded CBs, or a combination thereof.

In some examples of the method, apparatus, and non-transitory computer-readable medium described above, the packet comprises a transport block (TB) or a TB with a TB-level CRC.

A method of wireless communication is described. The method may include receiving a packet over a radio frequency spectrum based at least in part on a codeblock group (CBG) and a low-density parity-check (LDPC) encoding scheme and transmitting acknowledgement/non-acknowledgement (ACK/NACK) feedback for at least one CBG in the packet.

An apparatus for wireless communication is described. The apparatus may include means for receiving a packet over a radio frequency spectrum based at least in part on a codeblock group (CBG) and a low-density parity-check (LDPC) encoding scheme and means for transmitting acknowledgement/non-acknowledgement (ACK/NACK) feedback for at least one CBG in the packet.

Another apparatus for wireless communication is described. The apparatus may include a transceiver, a processor, memory in electronic communication with the processor, and instructions stored in the memory. The instructions may be operable to cause the processor to implement a wireless communication manager configured to receive, via the transceiver, a packet over a radio frequency spectrum based at least in part on a codeblock group (CBG) and a low-density parity-check (LDPC) encoding scheme and transmit acknowledgement/non-acknowledgement (ACK/NACK) feedback for at least one CBG in the packet.

A non-transitory computer readable medium for wireless communication is described. The non-transitory computer-readable medium may include instructions operable to cause a processor to receive, via a transceiver, a packet over a radio frequency spectrum based at least in part on a codeblock group (CBG) and a low-density parity-check (LDPC) encoding scheme and transmit acknowledgement/non-acknowledgement (ACK/NACK) feedback for at least one CBG in the packet.

Some examples of the method, apparatus, and non-transitory computer-readable medium described above may further include processes, features, means, or instructions for transmitting ACK/NACK feedback for each CBG in the packet.

In some examples of the method, apparatus, and non-transitory computer-readable medium described above, the CBG comprises a set of codeblocks (CBs) less than a total number of CBs in the packet.

Some examples of the method, apparatus, and non-transitory computer-readable medium described above may further include processes, features, means, or instructions for determining a cyclic redundancy check (CRC) value for the CBG. Some examples of the method, apparatus, and non-transitory computer-readable medium described above may further include processes, features, means, or instructions for verifying the CRC value. Some examples of the method, apparatus, and non-transitory computer-readable medium described above may further include processes, features, means, or instructions for generating the ACK/NACK feedback based at least in part on the verification of the CRC value.

In some examples of the method, apparatus, and non-transitory computer-readable medium described above, the CBG comprises a single codeblock (CB).

Some examples of the method, apparatus, and non-transitory computer-readable medium described above may further include processes, features, means, or instructions for determining a cyclic redundancy check (CRC) value for the CB. Some examples of the method, apparatus, and non-transitory computer-readable medium described above may further include processes, features, means, or instructions for verifying the CRC value. Some examples of the method, apparatus, and non-transitory computer-readable medium described above may further include processes, features, means, or instructions for generating the ACK/NACK feedback based at least in part on the verification of the CRC value.

Some examples of the method, apparatus, and non-transitory computer-readable medium described above may further include processes, features, means, or instructions for receiving a retransmission of the CBG based at least in part on the ACK/NACK feedback.

The foregoing has outlined rather broadly the techniques and technical advantages of examples according to the disclosure in order that the detailed description that follows may be better understood. Additional techniques and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purpose of illustration and description, and not as a definition of the limits of the claims.

### BRIEF DESCRIPTION OF THE DRAWINGS

A further understanding of the nature and advantages of the present disclosure may be realized by reference to the following drawings. In the appended figures, similar components or functions may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 shows an example of a wireless communication system, in accordance with various aspects of the present disclosure;

FIG. 2 shows an example of a channel coding chain, in accordance with various aspects of the present disclosure;

FIG. 3 shows example numbers of CBs associated with a CBG, in accordance with various aspects of the present disclosure;

FIG. 4 shows a block diagram of an apparatus for use in wireless communication, in accordance with various aspects of the present disclosure;

FIG. 5 shows a block diagram of a wireless communication manager at a receiving device for use in wireless communication, in accordance with various aspects of the present disclosure;

FIG. 6 shows a block diagram of a wireless communication manager at a transmitting device for use in wireless communication, in accordance with various aspects of the present disclosure;

FIG. 7 shows a block diagram of a UE for use in wireless communication, in accordance with various aspects of the present disclosure;

FIG. 8 shows a block diagram of a network access device for use in wireless communication, in accordance with various aspects of the present disclosure; and

FIG. 9 is a flow chart illustrating an example of a method for decoding packets including a set of CBGs over a data channel in accordance with various aspects of the present disclosure.

FIG. 10 is a flow chart illustrating an example of a method for decoding packets including a set of CBGs based at least in part on a default value of a parameter of a CBG in accordance with various aspects of the present disclosure

FIG. 11 is a flow chart illustrating an example of a method for determining whether to decode a packet based at least in part on a verification of the first CBG-level CRC in accordance with various aspects of the present disclosure.

FIG. 12 is a flow chart illustrating an example of a method for transmitting packets including a set of CBGs over a data channel.

FIG. 13 is a flow chart illustrating an example of a method for transmitting packets including a set of CBGs based at least in part on a default value of a parameter of a CBG in accordance with various aspects of the present disclosure.

FIG. 14 is a flow chart illustrating an example of a method for transmitting packets encoded based at least in part on a determined number of CBs associate with a CBG and a LDPC encoding scheme in accordance with various aspects of the present disclosure.

FIG. 15 is a flow chart illustrating an example of a method for transmitting packets encoded based at least in part on a LDPC encoding scheme in accordance with various aspects of the present disclosure.

FIG. 16 is a flow chart illustrating an example of a method for transmitting packets encoded based at least in part on a determined number of CBs associate with a CBG and a LDPC encoding scheme in accordance with various aspects of the present disclosure.

FIG. 17 is a flow chart illustrating an example of a method for decoding packets encoded based at least in part on a determined number of CBs associate with a CBG and a LDPC encoding scheme in accordance with various aspects of the present disclosure.

FIG. 18 is a flow chart illustrating an example of a method for determining whether to decode a packet based at least in part on a verification of a CBG-level CRC in accordance with various aspects of the present disclosure.

FIG. 19 is a flow chart illustrating an example of a method for transmitting ACK/NACK feedback for at least one CBG in accordance with various aspects of the present disclosure.

FIG. 20 is a flow chart illustrating an examples of a method for receiving ACK/NACK feedback for at least one CBG, in accordance with various aspects of the present disclosure.

### DETAILED DESCRIPTION

ACK/NACK feedback is sometimes provided at a packet-level, with an ACK or a NACK being generated for a packet based at least in part on the outcome of a CRC verification performed for the packet. An ACK or a NACK may also be generated for a packet based on parity checks performed for each of a plurality of codeblocks (CBs) in the packet. In some examples, parity checks may be performed based at least in part on a LDPC encoding scheme. While packet-level ACK/NACK feedback is useful, it may be useful to provide CBG-level ACK/NACK feedback in some cases (e.g., in the case of larger packet sizes). A CBG includes a set of CBs less than the total number of CBs included in a packet. In some examples, a CBG-level CRC may be generated for each CBG in a packet. A receiving wireless device that receives a CBG of a packet, but cannot verify a CBG-level CRC associated with the CBG, may terminate packet decoding early and conserve power. Additionally or alternatively, the receiving wireless device may provide a transmitting wireless device with CBG-level ACK/NACK feedback that allows the transmitting wireless device to retransmit one or more failed CBG transmissions instead of retransmitting an entire packet.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various operations may be added, omitted, or combined. Also, features described with respect to some examples may be combined in some other examples.

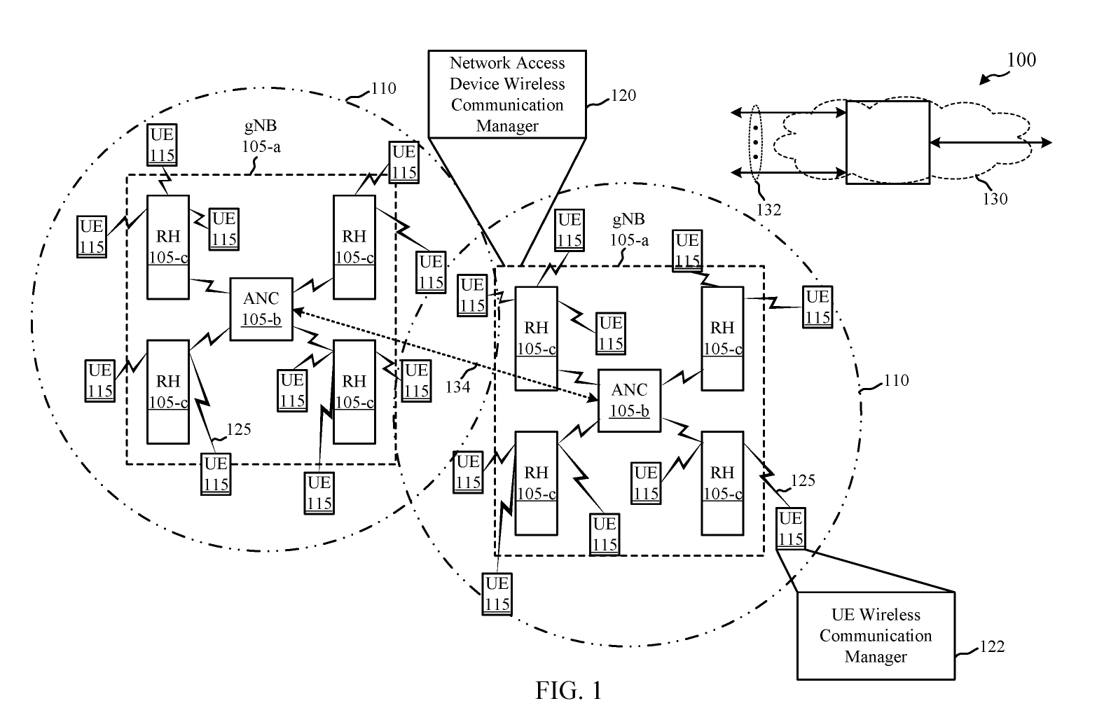

FIG. 1 shows an example of a wireless communication system 100, in accordance with various aspects of the present disclosure. The wireless communication system 100 may include network access devices 105 (e.g., gNBs 105-a, ANCs 105-b, and/or RHs 105-c), UEs 115, and a core network 130. The core network 130 may provide user authentication, access authorization, tracking, Internet Protocol (IP) connectivity, and other access, routing, or mobility functions. At least some of the network access devices 105 (e.g., gNBs 105-a or ANCs 105-b) may interface with the core network 130 through backhaul links 132 (e.g., S1, S2, etc.) and may perform radio configuration and scheduling for communication with the UEs 115. In various examples, the ANCs 105-b may communicate, either directly or indirectly (e.g., through core network 130), with each other over backhaul links 134 (e.g., X1, X2, etc.), which may be wired or wireless communication links. Each ANC 105-b may also communicate with a number of UEs 115 through a number of smart radio heads (e.g., RHs 105-c). In an alternative configuration of the wireless communication system 100, the functionality of an ANC 105-b may be provided by a RH 105-c or distributed across the RHs 105-c of an gNB 105-a. In another alternative configuration of the wireless communication system 100 (e.g., an LTE/LTE-A configuration), the RHs 105-c may be replaced with base stations, the ANCs 105-b may be replaced by base station controllers (or links to the core network 130), and the gNBs 105-a may be replaced by eNBs. In some examples, the wireless communication system 100 may include a mix of RHs 105-c, base stations, and/or other network access devices 105 for receiving/transmitting communications according to different radio access technologies (RATs) (e.g., LTE/LTE-A, 5G, Wi-Fi, etc.).

A macro cell may cover a relatively large geographic area (e.g., several kilometers in radius) and may allow unrestricted access by UEs 115 having service subscriptions with a network provider. A small cell may include a lower-powered radio head or base station, as compared with a macro cell, and may operate in the same or different frequency band(s) as macro cells. Small cells may include pico cells, femto cells, and micro cells according to various examples. A pico cell may cover a relatively smaller geographic area and may allow unrestricted access by UEs 115 with service subscriptions with a network provider. A femto cell also may cover a relatively small geographic area (e.g., a home) and may provide restricted access by UEs 115 having an association with the femto cell (e.g., UEs in a closed subscriber group (CSG), UEs for users in the home, and the like). A gNB for a macro cell may be referred to as a macro gNB. A gNB for a small cell may be referred to as a small cell gNB, a pico gNB, a femto gNB or a home gNB. A gNB may support one or multiple (e.g., two, three, four, and the like) cells (e.g., component carriers).

The wireless communication system 100 may support synchronous or asynchronous operation. For synchronous operation, the gNBs 105-a and/or RHs 105-c may have similar frame timing, and transmissions from different gNBs 105-a and/or RHs 105-c may be approximately aligned in time. For asynchronous operation, the gNBs 105-a and/or RHs 105-c may have different frame timings, and transmissions from different gNBs 105-a and/or RHs 105-c may not be aligned in time. The techniques described herein may be used for either synchronous or asynchronous operations.

The communication networks that may accommodate some of the various disclosed examples may be packet-based networks that operate according to a layered protocol stack. In the user plane, communications at the bearer or Packet Data Convergence Protocol (PDCP) layer may be IP-based. A Radio Link Control (RLC) layer may in some cases perform packet segmentation and reassembly to communicate over logical channels. A Medium Access Control (MAC) layer may perform priority handling and multiplexing of logical channels into transport channels. The MAC layer may also use Hybrid ARQ (HARD) to provide retransmission at the MAC layer to improve link efficiency. In the control plane, the Radio Resource Control (RRC) protocol layer may provide establishment, configuration, and maintenance of an RRC connection between a UE 115 and a RH 105-c, ANC 105-b, or core network 130 supporting radio bearers for user plane data. At the Physical (PHY) layer, transport channels may be mapped to physical channels.

The UEs 115 may be dispersed throughout the wireless communication system 100, and each UE 115 may be stationary or mobile. A UE 115 may also include or be referred to by those skilled in the art as a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. A UE 115 may be a cellular phone, a personal digital assistant (PDA), a wireless modem, a wireless communication device, a handheld device, a tablet computer, a laptop computer, a cordless phone, a wireless local loop (WLL) station, an Internet of Everything (IoE) device, etc. A UE 115 may be able to communicate with various types of network access devices 105 (e.g., gNBs 105-a, RHs 105-c, eNBs, base stations, access points, macro gNBs, small cell gNBs, relay base stations, and the like. A UE 115 may also be able to communicate directly with other UEs 115 (e.g., using a peer-to-peer (P2P) protocol).

The communication links 125 shown in wireless communication system 100 may include ULs, from a UE 115 to a RH 105-c, and/or DLs, from a RH 105-c to a UE 115. The DLs may also be called forward links, while the ULs may also be called reverse links. Control information and data may be multiplexed on a UL or DL according to various techniques. Control information and data may be multiplexed on a UL or DL, for example, using TDM techniques, FDM techniques, or hybrid TDM-FDM techniques.

In some examples, the channel coding scheme used for enhanced mobile broadband (eMBB) data (or other types of data) may include a LDPC encoding scheme. An LDPC encoding scheme may be used for a UL and/or a DL. In some examples, a LDPC encoding scheme may be supported with a large range and fine granularity or code rates and block lengths. However, practical implementations of a LDPC decoder may leverage a layered structure where parity checks are evaluated sequentially, and as a result, parity check results may be unreliable in indicating decoding failures or successes. For error detection based on LDPC decoder parity checks, the CB error miss rate (CBErrorMissRate) is defined as the rate at which a LDPC decoder parity check misses errors in erred CBs:

$$CBErrorMissRate = \frac{nCBErrorMiss}{nCBInError}$$

A CB error false alarm rate (CBErrorFARate) is defined as the rate at which a LDPC decoder parity check identifies errors in error-free CBs:

$$CBErrorFARate = \frac{nCBErrorFalseAlarm}{nCBCorrect}$$

Practical LDPC decoders having a layered structure may be associated with a non-negligible CBErrorMissRate and/or CBErrorFARate, even after parity checks or a maximum number of iteration exhausts—especially for small block lengths. In the case of a CB error miss and packet-level retransmission, a decoder may process additional CBs unnecessarily, resulting in a power waste. In the case of a CB error false alarm, a decoder may terminate decoding prematurely, leading to a packet-level NACK and an unnecessary packet retransmission.

Techniques described in the present disclosure may therefore provide an additional level of error detection between LDPC-encoded CB parity checks and a packet-level CRC (e.g., a TB-level CRC). The additional level of error detection includes CBG-level CRCs. A CBG-level CRC may be verified for each CBG of a packet. In response to a failed CBG-level CRC verification, packet decoding may be terminated (and sometimes terminated early), thereby conserving power. Also or alternatively, CBG-level ACK/NACK feedback (e.g., CBG-level HARQ ACK/NACK feedback) may be provided to a transmitting wireless device based on the outcome of a CBG-level CRC verification (and for each CBG-level CRC verification). CBG-level ACK/NACK feedback allows for improved spectral efficiency through finer-granularity retransmission or outer error correction code.

In some examples, CBG size may be approximately fixed, to allow for parallel processing and relatively low CBG-level CRC overhead. In some examples, CBG-level CRC length may vary depending on CB size, to reduce overhead and improve transmission efficiency. For example, a smaller CB size may be associated with a smaller CBG-level CRC or no CBG0level CRC.

Each communication link 125 may include one or more carriers, where each carrier may be a signal made up of multiple sub-carriers (e.g., waveform signals of different frequencies) modulated according to one or more radio access technologies. Each modulated signal may be sent on a different sub-carrier and may carry control information (e.g., reference signals, control channels, etc.), overhead information, user data, etc. The communication links 125 may transmit bidirectional communications using Frequency Division Duplexing (FDD) techniques (e.g., using paired spectrum resources) or Time Division Duplexing techniques (e.g., using unpaired spectrum resources). Frame structures for FDD (e.g., frame structure type 1) and TDD (e.g., frame structure type 2) may be defined.

In some examples of the wireless communication system 100, network access devices 105 (e.g., RHs 105-c) and UEs 115 may include multiple antennas for employing antenna diversity schemes to improve communication quality and reliability between network access devices 105 and UEs 115. Additionally or alternatively, network access devices and UEs 115 may employ MIMO techniques that may take advantage of multi-path environments to transmit multiple spatial layers carrying the same or different coded data. In some cases, signal processing techniques such as beamforming (i.e., directional transmission) may be used with MIMO techniques to coherently combine signal energies and overcome the path loss in specific beam directions. Precoding (e.g., weighting transmissions on different paths or layers, or from different antennas) may be used in conjunction with MIMO or beamforming techniques.

The wireless communication system 100 may support operation on multiple cells or carriers, a feature which may be referred to as carrier aggregation (CA) or multi-carrier operation. A carrier may also be referred to as a component carrier (CC), a layer, a channel, etc. The terms “carrier,” “component carrier,” “cell,” and “channel” may be used interchangeably herein. A UE 115 may be configured with multiple downlink CCs and one or more uplink CCs for carrier aggregation. Carrier aggregation may be used with both FDD and TDD component carriers.

In some examples, a network access device 105 may include a network access device wireless communication manager 120 and a UE 115 may include a UE wireless communication manager 122. The network access device wireless communication manager 120 or the UE wireless communication manager 122 may be used to receive a control channel and a data channel over a radio frequency spectrum, decode the control channel, and decode a packet received over the data channel. The control channel may indicate a parameter of a CBG. The parameter of the CBG may indicate at least one of a number of CBs associated with the CBG, a CBG size, a CBG-level CRC length, or a combination thereof. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may have been encoded based at least in part on a LDPC encoding scheme.

The network access device wireless communication manager 120 or the UE wireless communication manager 122 may also or alternatively be used to transmit a control channel over a radio frequency spectrum. The control channel may indicate a parameter of a CBG. The parameter of the CBG may indicate at least one of a number of CBs associated with the CBG, a CBG size, a CBG-level CRC length, or a combination thereof. The wireless communication manager 120 may also be used to transmit a packet over a data channel of the radio frequency spectrum. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may be encoded based at least in part on a LDPC encoding scheme.

The network access device wireless communication manager 120 or the UE wireless communication manager 122 may also or alternatively be used to determine a number of CBs associated with a CBG based at least in part on a parameter of a LDPC encoding scheme, and transmit, over a radio frequency spectrum, a packet encoded based at least in part on the determined number of CBs associated with the CBG and the LDPC encoding scheme.

The network access device wireless communication manager 120 or the UE wireless communication manager 122 may also or alternatively be used to determine a number of CBs associated with a CBG based at least in part on a parameter of a LDPC encoding scheme, and decode, based at least in part on the determined number of CBs associated with the CBG and the LDPC encoding scheme, a packet received over a radio frequency spectrum.

The network access device wireless communication manager 120 or the UE wireless communication manager 122 may also or alternatively be used to receive a packet over a radio frequency spectrum based at least in part on a CBG and a LDPC encoding scheme, and transmit ACK/NACK feedback for at least one CBG in the packet.

The network access device wireless communication manager 120 or the UE wireless communication manager 122 may also or alternatively be used to transmit a packet over a radio frequency spectrum based at least in part on a CBG and a LDPC encoding scheme, and receive ACK/NACK feedback for at least one CBG in the packet.

In some examples, the network access device wireless communication manager 120 may have different functionality than the UE wireless communication manager 122. For example, different network access device wireless communication managers 120 or UE wireless communication managers 122 in the wireless communications system may include different combinations of the functionality described above. Different network access device wireless communication managers 120 or UE wireless communication managers 122 may also be different versions of the same device, or may include functionality specific to either the network access device 105 or the UE 115.

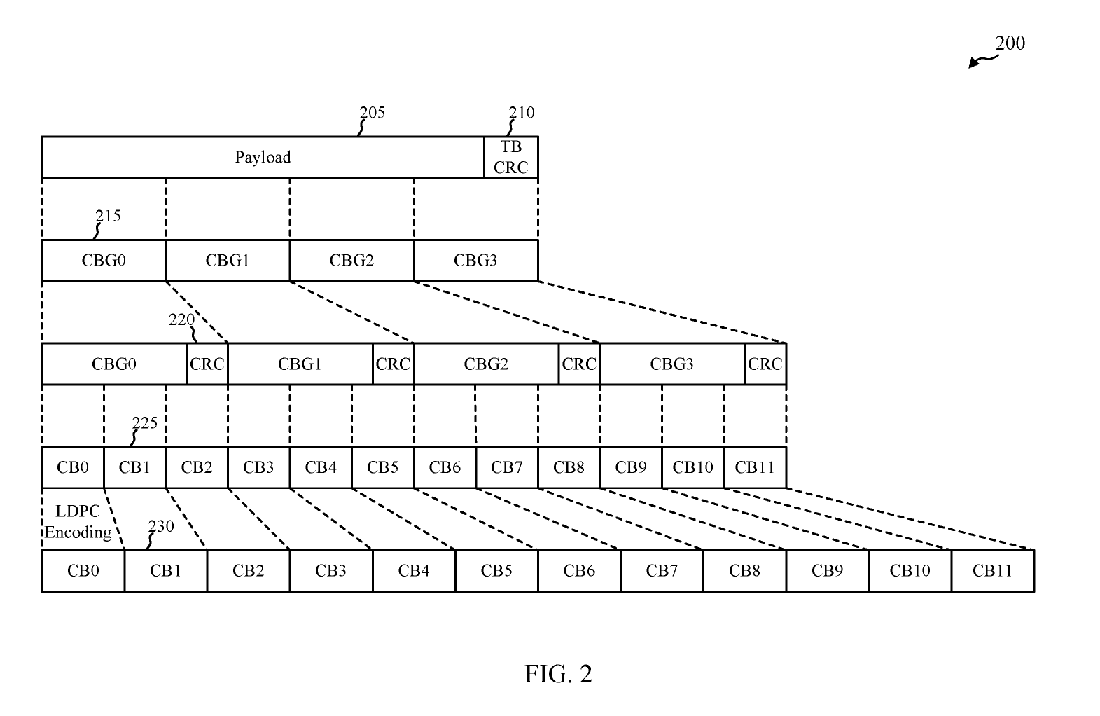

FIG. 2 shows an example of a channel coding chain 200, in accordance with various aspects of the present disclosure. The channel coding chain 200 may be used for a packet transmitted over a data channel of a radio frequency spectrum, and may be used by a wireless device such as a network access device or UE (e.g., a network access device 105 or a UE 115 described with reference to FIG. 1).

In accordance with the channel coding chain 200, a transmitting wireless device may generate an optional packet-level CRC 210 (e.g., a TB-level CRC) for a set of bits 205 (e.g., a payload or TB) to be transmitted over a data channel. The transmitting wireless device may segment the set of bits 205 (with or without the packet-level CRC 210) into a set of CBGs 215 (e.g., CBG0, CBG1, CBG2, and CBG3), and may generate a CBG-level CRC 220 for each CBG 215 in the set of CBGs. The transmitting wireless device may further segment each CBG 215 and corresponding CBG-level CRC 220 into a set of CBs 225 (e.g., [CB0:CB11]), and may encode each CB 225 based at least in part on a LDPC encoding scheme. The transmitting wireless device may transmit the encoded CBs 230 over the data channel in a packet.

When the transmitted packet is received by a receiving wireless device, the receiving wireless device may decode a set of encoded CBs 230 included in a CBG 215, and may extract a CBG-level CRC 220 from the set of decoded CBs 225. The receiving wireless device may verify the CBG-level CRC 220. Based at least in part on the verification of the CBG-level CRC 220, the receiving wireless device may determine whether to continue decoding the packet, whether to transmit ACK/NACK feedback for the set of decoded CBs 225, or a combination thereof.

In some examples, CBG-level CRCs may be selectively generated/transmitted for a packet when the addition of CBG-level CRCs to a packet will not unduly increase the overhead of the packet. In some examples, CBG-level CRCs may be selectively generated/transmitted for a packet as a function of (or based on) at least one of a number of MIMO transmission layers on which the packet is transmitted, a number of codewords included in the packet, a CB size, a code rate, or a combination thereof. For example, CBG-level CRCs may be generated/transmitted for a packet transmitted on a number of MIMO transmission layers that is equal to or greater than a threshold number of MIMO transmission layers, because transmitting on a greater number of MIMO transmission layers implies a higher data rate and a larger CB size. CBG-level CRCs may not be generated/transmitted for a packet transmitted on a number of MIMO transmission layers that is less than the threshold number of MIMO transmission layers. As another example, CBG-level CRCs may be generated/transmitted for a packet transmitted using a code rate that is equal to or greater than a threshold code rate, because the CBG-level CRCs may not unduly increase packet overhead. CBG-level CRCs may not be generated/transmitted for a packet transmitted using a code rate that is less than the threshold code rate.

In some examples, a length of a CBG-level CRC may be determined as a function of (or based on) at least one of a number of MIMO transmission layers on which the packet is transmitted, a number of codewords included in the packet, a CB size, a code rate, a packet-level CRC size (which in some cases be zero, indicating there is no packet-level CRC) or a combination thereof.

Because CBG-level CRCs may or may not be transmitted with a packet, a transmitting wireless device may indicate, to a receiving wireless device, whether CBG-level CRCs are transmitted with a packet. In some examples, the indication may be explicit. In other examples, the indication may be implicit. For example, a transmitting wireless device may indicate, to a receiving wireless device, a parameter of a CBG. The receiving wireless device may infer, from receipt or non-receipt of the indication of the parameter of the CBG, whether a packet is transmitted with CBG-level CRCs. In some examples, the parameter of the CBG may include, for example, at least one of a number of CBs associated with the CBG, a CBG size, a CBG-level CRC length, or a combination thereof. In some examples, the transmitting wireless device may transmit a control channel over a radio frequency spectrum, and may signal the parameter of the CBG in the control channel (e.g., in dedicated RRC signaling).

Prior to the transmitting wireless device transmitting the control channel indicating the at least one parameter of the CBG, and in some examples, the receiving wireless device may decode a transmission received over the radio frequency spectrum based at least in part on a default value of the parameter of the CBG. The default value may be obtained, by the receiving wireless device, from a broadcast channel received over the radio frequency spectrum, or from configuration information stored at the receiving wireless device. In some examples, the default value may be used to include (or decode) CBG-level CRCs in a Msg2, Msg3, or Msg4 of a 4-step random access channel (RACH) procedure, or in a Msg1+Msg3 of a 2-step RACH procedure.

In some examples, a default parameter of a CBG may be indicated in a broadcast channel over a radio frequency spectrum, and modified for a receiving wireless device in dedicated RRC signaling for the receiving wireless device.

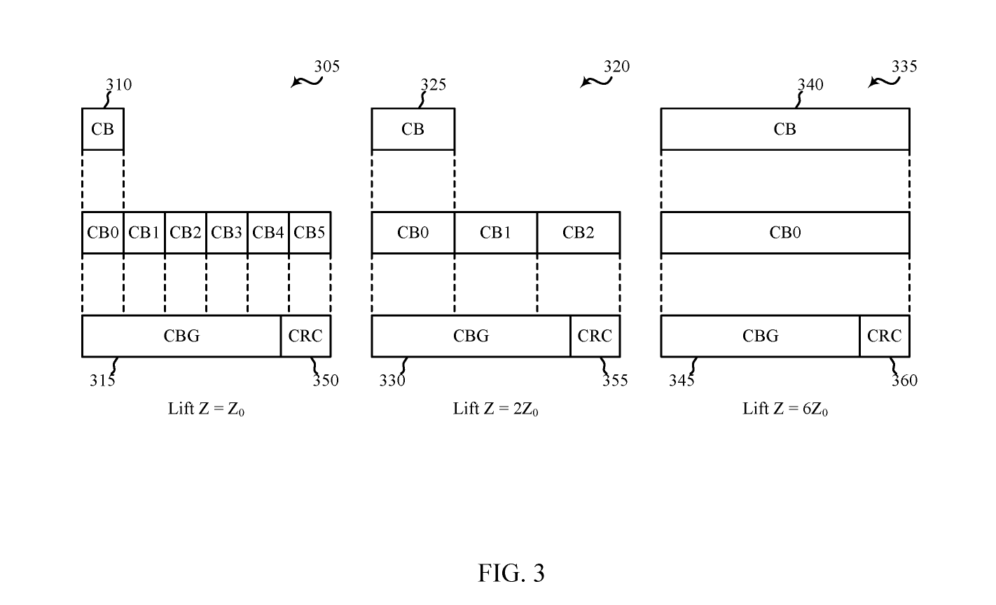

FIG. 3 shows example numbers of CBs associated with a CBG, in accordance with various aspects of the present disclosure. In a first example 305, six CBs 310 (e.g., [CB0:CB5]) are associated with a CBG 315. In a second example 320, three CBs 325 (e.g., [CB0:CB2]) are associated with a CBG 330. In a third example 335, one CB 340 (e.g., CB0) is associated with a CBG 345. As shown, a CBG may be associated with a CBG-level CRC 350, 355, or 360.

In some examples, a number of CBs associated with a CBG may be determined based at least in part on a parameter of a LDPC encoding scheme. In some examples, the parameter of the LDPC encoding scheme may include a lifting factor of the LDPC encoding scheme. Determining the number of CBs associated with a CBG based at least in part on a lifting factor of a LDPC encoding scheme allows efficient CBG-level CRC generation in a parallel pipelined structure. For example, the largest lifting factor, Z, may determine the level of parallelism in a packet decoder (i.e., the number of CBs that can be processed in parallel may depend on Z). Also, the CB size (e.g., block length) of the CBs associated with a CBG may roughly scale with Z.

In some examples, a CBG size may be restrained to a fixed number of information bits, or to a number of information bits within a small range (e.g., [24:30] bits). Restraining the CBG size may allow a single CBG-level CRC length for all CBGs, regardless of the number of CBs associated with a CBG.

In some examples, a CBG size (L_{CBG}) and a length of a CBG-level CRC (L_{CRC}) may be determined to maintain packet CRC overhead (where CBG CRC Overhead=(L_{CRC}/L_{CBG}) at a relatively low level while providing a required error detection capability.

In some examples, CBG-level CRCs may provide a basis for transmission of CBG-level ACK/NACK feedback. The transmission of CBG-level ACK/NACK feedback can provide enhanced performance with the addition of a reasonable amount of control overhead. In some examples, the control overhead may be based on a worst case number (i.e., maximum number) of CBGs per packet, which may be:

$${R}_{ma x} \cdot \frac{{N}_{SC} \cdot {N}_{mod} \cdot {N}_{layer}}{{L}_{CBG}}$$

CB error for a transmission may be bursty in a low-selective fading channel, or when a transmission is transmitted concurrently with mission critical traffic.

When performing a CBG-level retransmission, incremental redundancy HARQ (IR-HARQ) may be used, with each CB in a retransmission of a failed CBG (i.e., a CBG that was NACK'd by a receiving wireless device) including additional redundant bits in a parity check matrix (PCM). CBG-level retransmission may allow a promised IR-HARQ gain to be better realized than TB-level retransmission. Alternatively an outer-code may be used to recover a failed CBG.

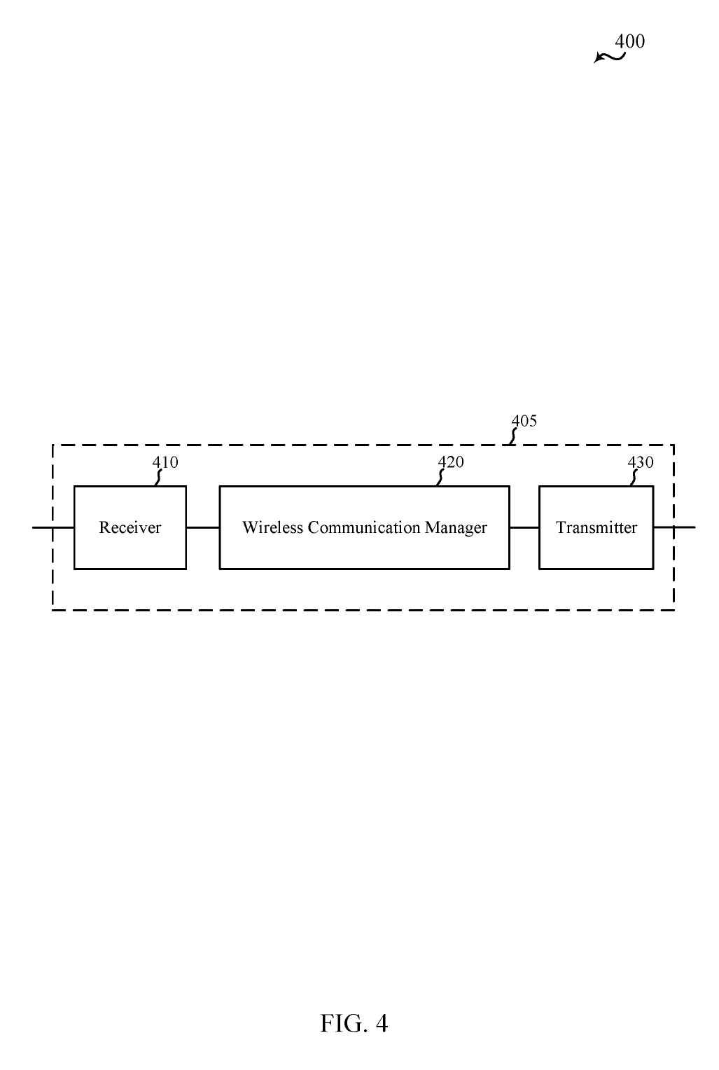

FIG. 4 shows a block diagram 400 of an apparatus 405 for use in wireless communication, in accordance with various aspects of the present disclosure. The apparatus 405 may be an example of aspects of a wireless device (e.g., a network access device or UE), such as one or more of the network access devices (e.g., a RH, an ANC, or a gNB) or UEs described with reference to FIG. 1. The apparatus 405 may also be or include a processor. The apparatus 405 may include a receiver 410, a wireless communication manager 420, or a transmitter 430. Each of these components may be in communication with each other.

The components of the apparatus 405 may, individually or collectively, be implemented using one or more ASICs adapted to perform some or all of the applicable functions in hardware. Alternatively, the functions may be performed by one or more other processing units (or cores), on one or more integrated circuits. In some other examples, other types of integrated circuits may be used (e.g., Structured/Platform ASICs, FPGAs, a SoC, and/or other types of Semi-Custom ICs), which may be programmed in any manner known in the art. The functions of each component may also be implemented, in whole or in part, with instructions embodied in a memory, formatted to be executed by one or more general or application-specific processors.

In some examples, the receiver 410 may include at least one RF receiver, such as at least one RF receiver operable to receive transmissions over one or more radio frequency spectrums. In some examples, the one or more radio frequency spectrums may be used for communicating as described with reference to FIG. 1, 2, or 3. The receiver 410 may be used to receive various types of data or control signals (i.e., transmissions) over one or more communication links of a wireless communication system, such as one or more communication links of the wireless communication system 100 described with reference to FIG. 1.

In some examples, the transmitter 430 may include at least one RF transmitter, such as at least one RF transmitter operable to transmit over one or more radio frequency spectrums. In some examples, the one or more radio frequency spectrums may be used for communicating as described with reference to FIG. 1, 2, or 3. The transmitter 430 may be used to transmit various types of data or control signals (i.e., transmissions) over one or more communication links of a wireless communication system, such as one or more communication links of the wireless communication system 100 described with reference to FIG. 1.

In some examples, the wireless communication manager 420 may be used to manage one or more aspects of wireless communication for the apparatus 405. In some examples, part of the wireless communication manager 420 may be incorporated into or shared with the receiver 410 or the transmitter 430.

In some examples, the wireless communication manager 420 may be used to transmit and/or receive a packet over a data channel over a radio frequency spectrum. The packet may include a set of CBGs. Each CBG of the set of CBGs may be associated with a set of encoded CBs and a CBG-level CRC. Each encoded CB may have been encoded based at least in part on a LDPC encoding scheme. The CBG-level CRCs may be used as a means to verify whether a set of CBs representing just part of the packet have been correctly decoded, thereby enabling early termination of a packet decode (and power conservation) when a packet-level retransmission is needed. Verification of the CBG-level CRCs may also allow for transmission of CBG-level ACK/NACK feedback, which may enable finer-granularity retransmissions (e.g., CBG-level retransmissions instead of packet-level retransmissions). In some examples, a received packet may include a TB, or a TB with a TB-level CRC.

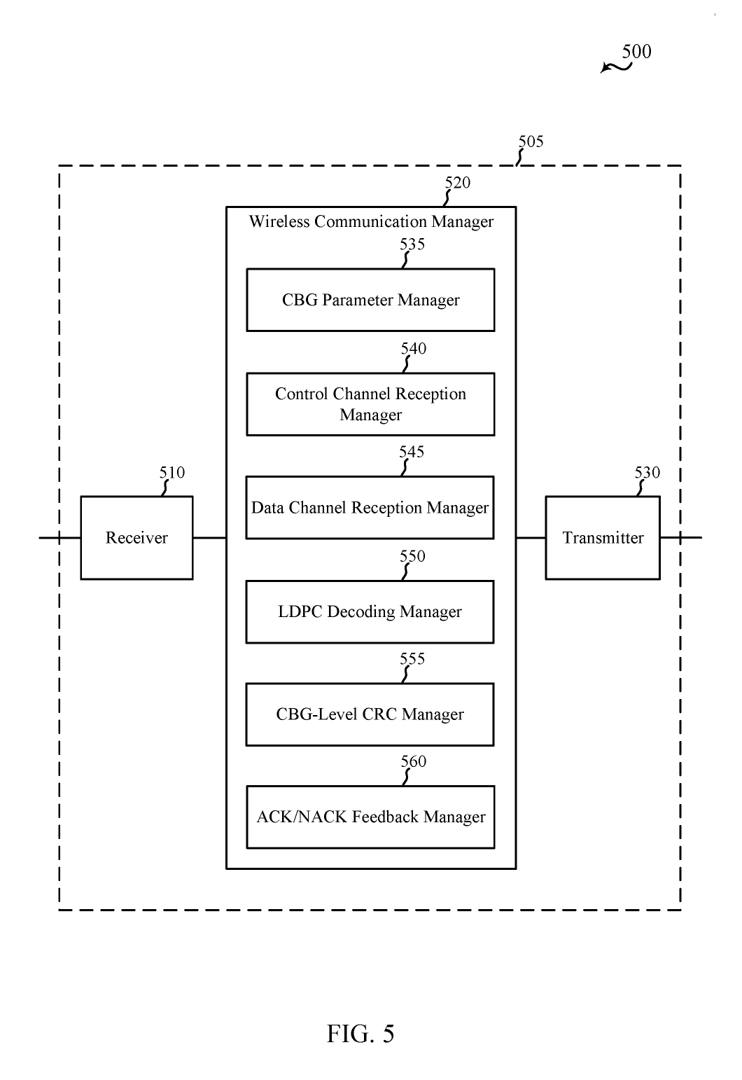

FIG. 5 shows a block diagram 500 of a wireless communication manager 520 for use in wireless communication, in accordance with various aspects of the present disclosure. The wireless communication manager 520 may be an example of aspects of the wireless communication manager described with reference to FIG. 1 or 4. The wireless communication manager 520 may be a component of a wireless device 505 such as network access device 105 or UE 115 described with reference to FIG. 1.

The components of the wireless communication manager 520 may, individually or collectively, be implemented using one or more ASICs adapted to perform some or all of the applicable functions in hardware. Alternatively, the functions may be performed by one or more other processors (or cores), on one or more integrated circuits. In some other examples, other types of integrated circuits may be used (e.g., Structured/Platform ASICs, FPGAs, a SoC, and/or other types of Semi-Custom ICs), which may be programmed in any manner known in the art. The functions of each component may also be implemented, in whole or in part, with instructions embodied in a memory, formatted to be executed by one or more general or application-specific processors.

In some examples, the wireless communication manager 520 may be used to manage one or more aspects of wireless communication for a wireless device (e.g., a network access device, UE, or apparatus, such as one of the network access devices, UEs, or apparatus described with reference to FIG. 1 or 4. In some examples, all or part of the wireless communication manager 520 may be incorporated into or shared with a receiver or a transmitter (e.g., the receiver 410 or the transmitter 430 described with reference to FIG. 4). In some examples, the wireless communication manager 520 may include a CBG parameter manager 535, a control channel reception manager 540, a data channel reception manager 545, a LDPC decoding manager 550, a CBG-level CRC manager 555, an ACK/NACK feedback manager 560, or some combination thereof.

The control channel reception manager 540 may be used to receive a control channel over a radio frequency spectrum, and to decode the control channel. The control channel may indicate a parameter of a CBG. The parameter of the CBG may indicate at least one of a number of CBs associated with the CBG, a CBG size, a CBG-level CRC length, or a combination thereof. In some examples, the control channel may indicate the parameter of the CBG by indicating a modification to a default value of a parameter of a CBG.

The CBG parameter manager 535 may be used to manage a parameter or parameters of a CBG. In some examples, the CBG parameter manager 535 may also be used to obtain a default value of a parameter of a CBG. In some examples, the default value may be obtained from a broadcast channel received over a radio frequency spectrum, or from configuration information stored at the wireless device. In some examples, the default value may be indicated in RRC signaling.

In some examples, the CBG parameter manager 535 may be used to determine a number of CBs associated with a CBG based at least in part on a parameter of a LDPC encoding scheme. In some examples, the parameter of the LDPC encoding scheme may include a lifting factor. In some examples, the number of CBs associated with the CBG may also be determined based at least in part on a CBG size restraint. In some examples, the number of CBs associated with the CBG may also be determined based on at least one of a number of MIMO transmission layers on which the packet is received, a number of codewords included in the packet, a CB size, a code rate, or a combination thereof.

In some examples, the CBG parameter manager 535 may be used to determine a length of CBG-level CRCs included in the packet based on at least one of the number of MIMO transmission layers on which the packet is received, the number of codewords included in the packet, the CB size, the code rate, a packet-level CRC size (which in some cases be zero, indicating there is no packet-level CRC), or a combination thereof.

The data channel reception manager 545 may be used to receive a data channel over the radio frequency spectrum, and to initiate a decode of a packet received over the data channel. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may have been encoded based at least in part on a LDPC encoding scheme. In some examples, the packet may be decoded based at least in part on a number of CBs associated with a CBG, as determined by the CBG parameter manager 535. In some examples, the packet may include a TB, or a TB with a TB-level CRC.

In some examples, the data channel reception manager 545 may also be used to initiate a decode of a transmission received over the radio frequency spectrum based at least in part on the default value of the parameter of the CBG, prior to the control channel reception manager 540 decoding the control channel.

The LDPC decoding manager 550 may be used to decode each encoded CB in a set of encoded CBs based at least in part on the LDPC encoding scheme.

The CBG-level CRC manager 555 may be used to extract from a set of decoded CBs, based at least in part on the parameter of the CBG, a CBG-level CRC. The CBG-level CRC manager 555 may also be used to verify the CBG-level CRC, and to determine, based at least in part on the verification of the CBG-level CRC, whether to continue decoding the packet, whether to transmit ACK/NACK feedback for the set of decoded CBs, or a combination thereof.

The ACK/NACK feedback manager 560 may be used to transmit ACK/NACK feedback for at least one CBG in a packet.

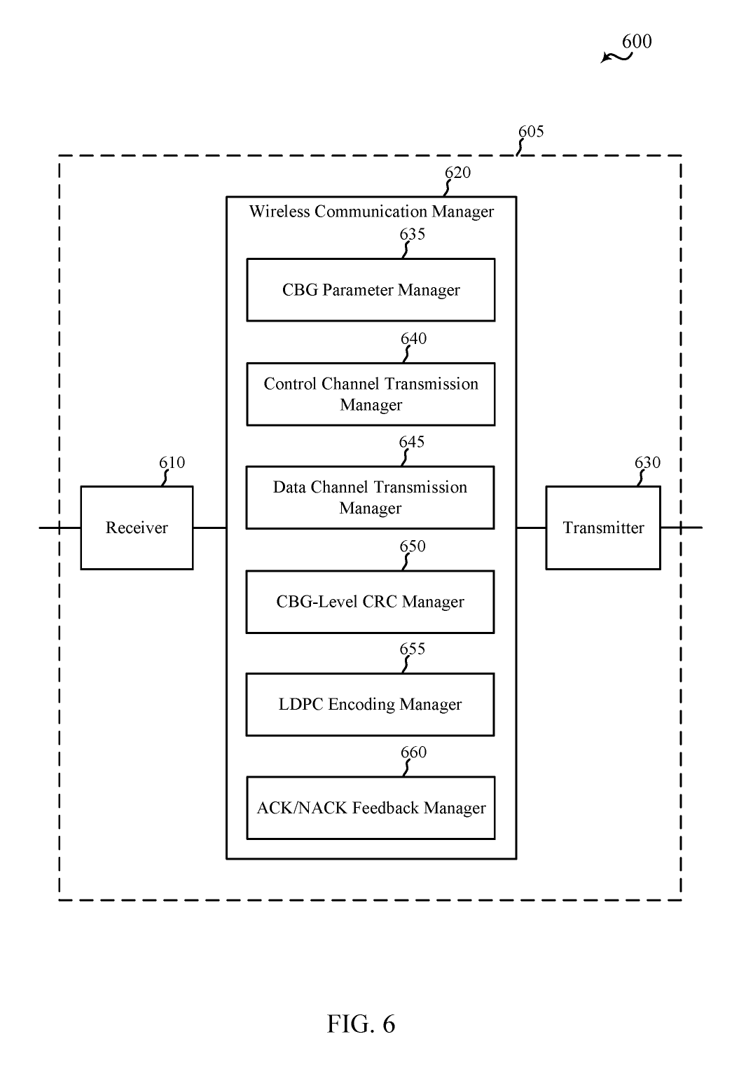

FIG. 6 shows a block diagram 600 of a wireless communication manager 620 for use in wireless communication, in accordance with various aspects of the present disclosure. The wireless communication manager 620 may be an example of aspects of the wireless communication manager described with reference to FIG. 1 or 4. The wireless communications manager 620 may be a component of a transmitting wireless device 605, which may be an example of aspects of network access device 105 or UE 115 as described with reference to FIG. 1.

The components of the wireless communication manager 620 may, individually or collectively, be implemented using one or more ASICs adapted to perform some or all of the applicable functions in hardware. Alternatively, the functions may be performed by one or more other processing units (or cores), on one or more integrated circuits. In some other examples, other types of integrated circuits may be used (e.g., Structured/Platform ASICs, FPGAs, a SoC, and/or other types of Semi-Custom ICs), which may be programmed in any manner known in the art. The functions of each component may also be implemented, in whole or in part, with instructions embodied in a memory, formatted to be executed by one or more general or application-specific processors.

In some examples, the wireless communication manager 620 may be used to manage one or more aspects of wireless communication for a wireless device (e.g., a network access device, UE, or apparatus, such as one of the network access devices, UEs, or apparatus described with reference to FIG. 1 or 4. In some examples, part of the wireless communication manager 620 may be incorporated into or shared with a receiver or a transmitter (e.g., the receiver 410 or the transmitter 430 described with reference to FIG. 4). In some examples, the wireless communication manager 620 may include a CBG parameter manager 635, a control channel transmission manager 640, a data channel transmission manager 645, a LDPC encoding manager 655, a CBG-level CRC manager 650, or an ACK/NACK feedback manager 660.

The CBG parameter manager 635 may be used to manage a parameter or parameters of a CBG. In some examples, the CBG parameter manager 635 may also be used to broadcast a default value of a parameter of a CBG over a radio frequency spectrum, prior to the control channel transmission manager 640 transmitting a control channel.

In some examples, the CBG parameter manager 635 may also be used to determine a number of CBs associated with a CBG, based at least in part on a parameter of a LDPC encoding scheme. In some examples, the parameter of the LDPC encoding scheme may include a lifting factor. In some examples, the number of CBs associated with the CBG may also be determined based at least in part on a CBG size restraint. In some examples, the number of CBs associated with the CBG may also be determined based on at least one of a number of MIMO transmission layers on which the packet is transmitted, a number of codewords included in the packet, a CB size, a code rate, or a combination thereof.

In some examples, the CBG parameter manager 635 may be used to determine a length of the CBG-level CRCs based on at least one of the number of MIMO transmission layers on which the packet is transmitted, the number of codewords included in the packet, the CB size, the code rate, a packet-level CRC size (which in some cases be zero, indicating there is no packet-level CRC), or a combination thereof.

The control channel transmission manager 640 may be used to transmit a control channel over a radio frequency spectrum. The control channel may indicate a parameter of a CBG. The parameter of the CBG may indicate at least one of a number of CBs associated with the CBG, a CBG size, a CBG-level CRC length, or a combination thereof. In some examples, the control channel may indicate the parameter of the CBG by indicating a modification to a default value of a parameter of a CBG.

The data channel transmission manager 645 may be used to transmit a packet over a data channel of the radio frequency spectrum. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may be encoded based at least in part on a LDPC encoding scheme. In some examples, the packet may be encoded based at least in part on a number of CBs associated with a CBG, as determined by the CBG parameter manager 635. In some examples, the packet may include a TB, or a TB with TB-level CRC.

In some examples, the data channel transmission manager 645 may be used to segment a set of bits into a set of CBGs, and to segment each CBG and corresponding CBG-level CRC into a set of CBs based at least in part on a determined number of CBs associated with a CBG.

The CBG-level CRC manager 650 may be used to generate a CBG-level CRC for each CBG in the set of CBGs.

In some examples, the CBG-level CRC manager 650 may also be used to determine whether to transmit CBG-level CRCs for a packet. The determination may be based on at least one of a number of MIMO transmission layers on which a packet is transmitted, a number of codewords included in the packet, a CB size, a code rate, or a combination thereof.

The LDPC encoding manager 655 may be used to encode each CB based at least in part on the LDPC encoding scheme. In some examples, transmitting a packet over the radio frequency spectrum may include transmitting the encoded CBs of a packet over the radio frequency spectrum.

The ACK/NACK feedback manager 660 may be used to receive ACK/NACK feedback for at least one CBG in the packet.

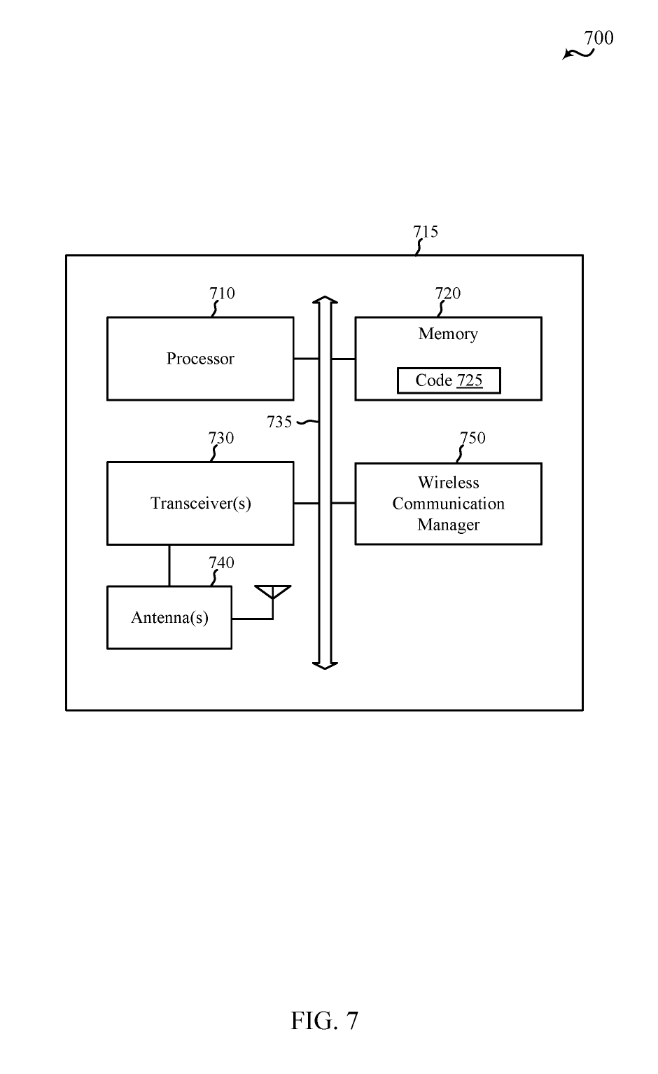

FIG. 7 shows a block diagram 700 of a UE 715 for use in wireless communication, in accordance with various aspects of the present disclosure. The UE 715 may be included or be part of a personal computer (e.g., a laptop computer, a netbook computer, a tablet computer, etc.), a cellular telephone, a PDA, a digital video recorder (DVR), an internet appliance, a gaming console, an e-reader, a vehicle, a home appliance, a lighting or alarm control system, or other wireless device. The UE 715 may, in some examples, have an internal power supply (not shown), such as a small battery, to facilitate mobile operation. In some examples, the UE 715 may be an example of aspects of one or more of the UEs described with reference to FIG. 1, or aspects of the apparatus described with reference to FIG. 4. The UE 715 may be configured to implement at least some of the UE or apparatus techniques or functions described with reference to FIG. 1, 2, 3, 4, 5, or 6.

The UE 715 may include a processor 710, a memory 720, at least one transceiver (represented by transceiver(s) 730), at least one antenna (represented by antenna(s) 740), or a wireless communication manager 750. Each of these components may be in communication with each other, directly or indirectly, over one or more buses 735.

The memory 720 may include random access memory (RAM) or read-only memory (ROM). The memory 720 may store computer-readable, computer-executable code 725 containing instructions that are configured to, when executed, cause the processor 710 in collaboration with the transceiver 730 to perform various functions described herein related to wireless communication, including, for example, functions described with reference to any of FIGS. 1-6 and 9-20. Alternatively, the computer-executable code 725 may not be directly executable by the processor 710 but be configured to cause the UE 715 (e.g., when compiled and executed) to perform various of the functions described herein.

The processor 710 may include an intelligent hardware device, e.g., a central processing unit (CPU), a microcontroller, an ASIC, etc. The processor 710 may process information received through the transceiver(s) 730 or information to be sent to the transceiver(s) 730 for transmission through the antenna(s) 740. The processor 710 may handle, alone or in connection with the wireless communication manager 750, one or more aspects of communicating over (or managing communications over) one or more radio frequency spectrums.

The transceiver(s) 730 may include a modem configured to modulate packets and provide the modulated packets to the antenna(s) 740 for transmission, and to demodulate packets received from the antenna(s) 740. The transceiver(s) 730 may, in some examples, be implemented as one or more transmitters and one or more separate receivers. The transceiver(s) 730 may support communications in one or more radio frequency spectrums. The transceiver(s) 730 may be configured to communicate bi-directionally, via the antenna(s) 740, with one or more network access devices or apparatuses, such as one or more of the network access devices described with reference to FIG. 1, or the apparatus described with reference to FIG. 4. The transceiver(s) 730 may also be configured to communicate bi-directionally, via the antenna(s) 740, with one or more other UEs.

The wireless communication manager 750 may be configured to perform or control some or all of the UE or apparatus techniques or functions described with reference to FIG. 1, 2, 3, 4, 5, or 6 related to wireless communication. The wireless communication manager 750, or portions of it, may include a processor, or some or all of the functions of the wireless communication manager 750 may be performed by or in connection with the processor 710, the memory 720, and the transceiver 730. In some examples, the wireless communication manager 750 may be an example of aspects of the wireless communication manager described with reference to FIG. 1, 4, 5, or 6.

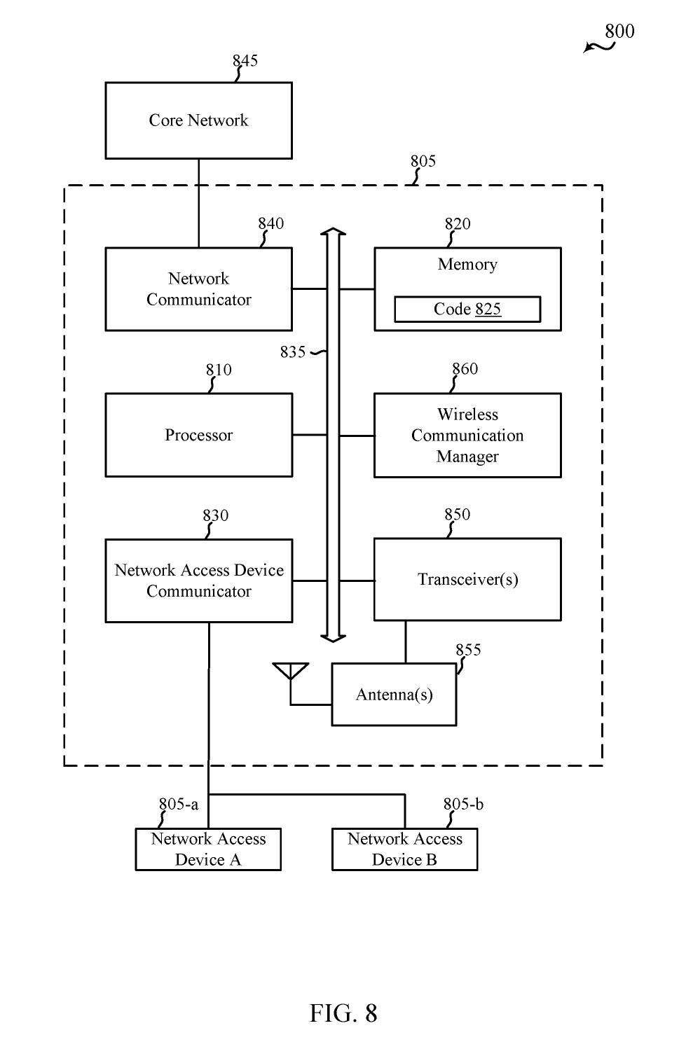

FIG. 8 shows a block diagram 800 of a network access device 805 for use in wireless communication, in accordance with various aspects of the present disclosure. In some examples, the network access device 805 may be an example of aspects of one or more of the network access devices (e.g., RHs, ANCs, or gNBs) described with reference to FIG. 1, or aspects of the apparatus described with reference to FIG. 4. The network access device 805 may be configured to implement or facilitate at least some of the network access device or apparatus techniques or functions described with reference to FIG. 1, 2, 3, 4, 5, or 6.

The network access device 805 may include a processor 810, a memory 820, at least one transceiver (represented by transceiver(s) 850), at least one antenna (represented by antenna(s) 855), or a wireless communication manager 860. The network access device 805 may also include one or more of a network access device communicator 830 or a network communicator 840. Each of these components may be in communication with each other, directly or indirectly, over one or more buses 835.

The memory 820 may include RAM or ROM. The memory 820 may store computer-readable, computer-executable code 825 containing instructions that are configured to, when executed, cause the processor 810 in collaboration with the transceiver 850 to perform various functions described herein related to wireless communication, including, for example, functions described with reference to any of FIGS. 1-6 and 9-20. Alternatively, the computer-executable code 825 may not be directly executable by the processor 810 but be configured to cause the network access device 805 (e.g., when compiled and executed) to perform various of the functions described herein.

The processor 810 may include an intelligent hardware device, e.g., a CPU, a microcontroller, an ASIC, etc. The processor 810 may process information received through the transceiver(s) 850, the network access device communicator 830, or the network communicator 840. The processor 810 may also process information to be sent to the transceiver(s) 850 for transmission through the antenna(s) 855, or to the network access device communicator 830 for transmission to one or more other network access devices (e.g., network access device 805-a or network access device 805-b), or to the network communicator 840 for transmission to a core network 845, which may be an example of one or more aspects of the core network 130 described with reference to FIG. 1. The processor 810 may handle, alone or in connection with the wireless communication manager 860, one or more aspects of communicating over (or managing communications over) one or more radio frequency spectrums.

The transceiver(s) 850 may include a modem configured to modulate packets and provide the modulated packets to the antenna(s) 855 for transmission, and to demodulate packets received from the antenna(s) 855. The transceiver(s) 850 may, in some examples, be implemented as one or more transmitters and one or more separate receivers. The transceiver(s) 850 may support communications in one or more radio frequency spectrums. The transceiver(s) 850 may be configured to communicate bi-directionally, via the antenna(s) 855, with one or more UEs or apparatuses, such as one or more of the UEs described with reference to FIG. 1 or 7, or the apparatus described with reference to FIG. 4. The network access device 805 may communicate with the core network 845 through the network communicator 840. The network access device 805 may also communicate with other network access devices, such as the network access device 805-a or the network access device 805-b, using the network access device communicator 830.

The wireless communication manager 860 may be configured to perform or control some or all of the network access device or apparatus techniques or functions described with reference to FIG. 1, 2, 3, 4, 5, or 6 related to wireless communication. The wireless communication manager 860, or portions of it, may include a processor, or some or all of the functions of the wireless communication manager 860 may be performed by or in connection with the processor 810, the memory 820, and the transceiver 850. In some examples, the wireless communication manager 860 may be an example of aspects of the wireless communication manager described with reference to FIG. 1, 4, 5, or 6.

In some examples, the components of the network access device 805 may be distributed across an ANC and one or more smart radio heads. In these examples, aspects of the processor 810, memory 820, transceiver(s) 850, antenna(s) 855, or wireless communication manager 860 may be implemented by and/or replicated in each of a number of smart radio heads, and the same or other aspects of the network access device 805 may be implemented by an ANC.

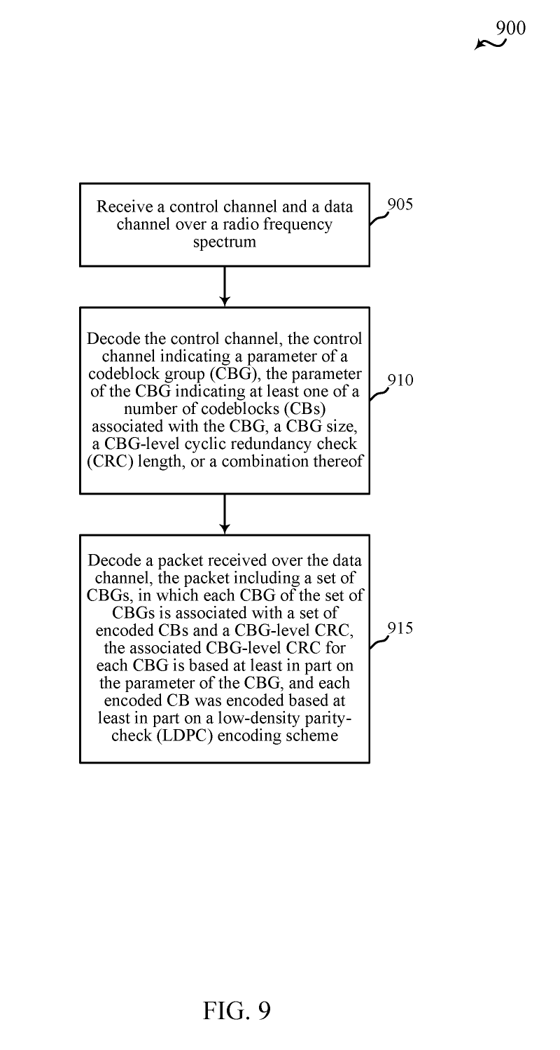

FIG. 9 is a flow chart illustrating an example of a method 900 for wireless communication at a wireless device, in accordance with various aspects of the present disclosure. For clarity, the method 900 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 5, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 905, the method 900 may include receiving a control channel and a data channel over a radio frequency spectrum. In certain examples, the operation(s) at block 905 may be performed using the control channel reception manager 540 or data channel reception manager 545 described with reference to FIG. 5.

At block 910, the method 900 may include decoding the control channel. The control channel may indicate a parameter of a CBG. The parameter of the CBG may indicate at least one of a number of CBs associated with the CBG, a CBG size, a CBG-level CRC length, or a combination thereof. In certain examples, the operation(s) at block 910 may be performed using the CBG parameter manager 535 or control channel reception manager 540 described with reference to FIG. 5.

At block 915, the method 900 may include decoding a packet received over the data channel. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may have been encoded based at least in part on a LDPC encoding scheme. In some examples, the packet may include a TB, or a TB with a TB-level CRC. In certain examples, the operation(s) at block 915 may be performed using the data channel reception manager 545, the LDPC decoding manager 550, or the CBG-level CRC manager 555 described with reference to FIG. 5.

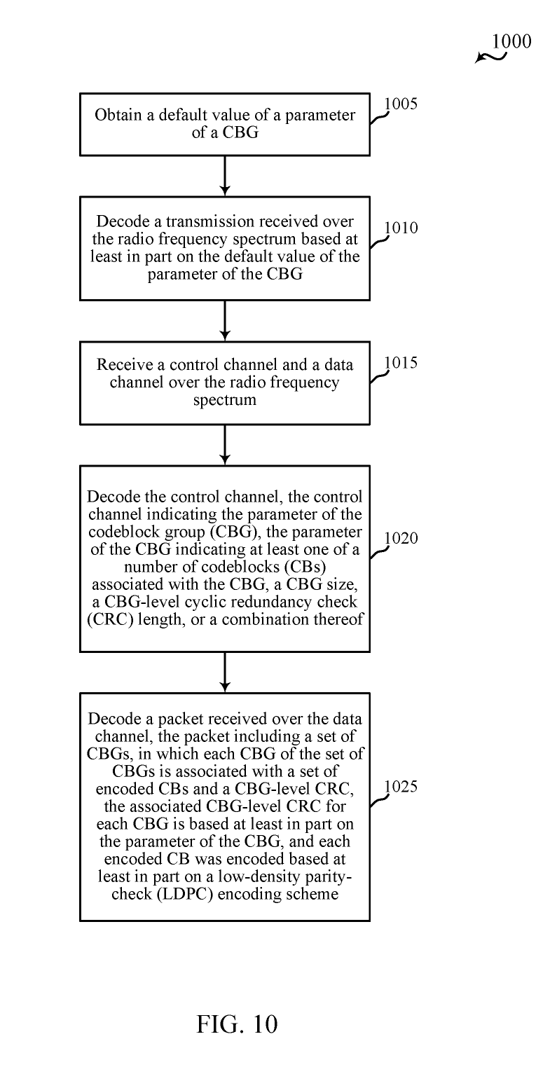

FIG. 10 is a flow chart illustrating an example of a method 1000 for wireless communication at a wireless device, in accordance with various aspects of the present disclosure. For clarity, the method 1000 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 5, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1005, the method 1000 may include obtaining a default value of a parameter of a CBG. The parameter of the CBG may indicate at least one of a number of CBs associated with the CBG, a CBG size, a CBG-level CRC length, or a combination thereof. In some examples, the default value may be obtained from a broadcast channel received over a radio frequency spectrum, or from configuration information stored at the wireless device. The default value may be indicated in RRC signaling. In certain examples, the operation(s) at block 1005 may be performed using CBG parameter manager 535 described with reference to FIG. 5.

At block 1010, and prior to decoding a control channel at block 1020, the method 1000 may include decoding a transmission received over a radio frequency spectrum based at least in part on the default value of the parameter of the CBG. In certain examples, the operation(s) at block 1010 may be performed using the data channel reception manager 545 described with reference to FIG. 5.

At block 1015, the method 1000 may include receiving a control channel and a data channel over the radio frequency spectrum. In certain examples, the operation(s) at block 1015 may be performed using the control channel reception manager 540 or data channel reception manager 545 described with reference to FIG. 5.

At block 1020, the method 1000 may include decoding the control channel. The control channel may indicate the parameter of the CBG. The parameter may indicate at least one of a number of CBs associated with the CBG, a CBG size, a CBG-level CRC length, or a combination thereof. In some examples, the control channel may indicate the parameter of the CBG by indicating a modification to the default value of the parameter of the CBG. In certain examples, the operation(s) at block 1020 may be performed using the CBG parameter manager 535 or control channel reception manager 540 described with reference to FIG. 5.

At block 1025, the method 1000 may include decoding a packet received over the data channel. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may have been encoded based at least in part on a LDPC encoding scheme. In some examples, the packet may include a TB, or a TB with a TB-level CRC. In certain examples, the operation(s) at block 1025 may be performed using the data channel reception manager 545, the LDPC decoding manager 550, or the CBG-level CRC manager 555 described with reference to FIG. 5.

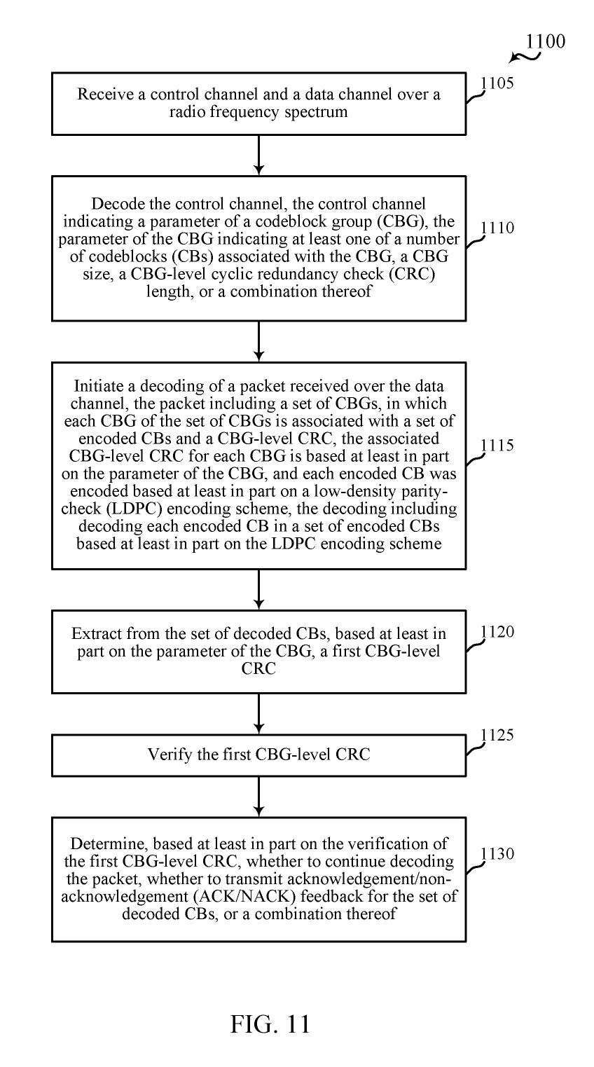

FIG. 11 is a flow chart illustrating an example of a method 1100 for wireless communication at a wireless device, in accordance with various aspects of the present disclosure. For clarity, the method 1100 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 5, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1105, the method 1100 may include receiving a control channel and a data channel over a radio frequency spectrum. In certain examples, the operation(s) at block 1105 may be performed using the control channel reception manager 540 or data channel reception manager 545 described with reference to FIG. 5.

At block 1110, the method 1100 may include decoding the control channel. The control channel may indicate a parameter of a CBG. The parameter of the CBG may indicate at least one of a number of CBs associated with the CBG, a CBG size, a CBG-level CRC length, or a combination thereof. In certain examples, the operation(s) at block 1110 may be performed using the CBG parameter manager 535 or control channel reception manager 540 described with reference to FIG. 5.

At block 1115, the method 1100 may include initiating the decoding of a packet received over the data channel. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may have been encoded based at least in part on a LDPC encoding scheme. Decoding the packet may include decoding each encoded CB in a set of encoded CBs based at least in part on the LDPC encoding scheme. In some examples, the packet may include a TB, or a TB with a TB-level CRC. In certain examples, the operation(s) at block 1115 may be performed using the data channel reception manager 545, the LDPC decoding manager 550, or the CBG-level CRC manager 555 described with reference to FIG. 5.

At block 1120, the method 1100 may include extracting from a set of decoded CBs, based at least in part on the parameter of the CBG, a first CBG-level CRC. In certain examples, the operation(s) at block 1120 may be performed using the CBG-level CRC manager 555 described with reference to FIG. 5.

At block 1125, the method 1100 may include verifying the first CBG-level CRC. In certain examples, the operation(s) at block 1125 may be performed using the CBG-level CRC manager 555 described with reference to FIG. 5.

At block 1130, the method 1100 may include determining, based at least in part on the verification of the first CBG-level CRC, whether to continue decoding the packet, whether to transmit acknowledgement/non-acknowledgement (ACK/NACK) feedback for the set of decoded CBs, or a combination thereof. In certain examples, the operation(s) at block 1130 may be performed using the CBG-level CRC manager 555 described with reference to FIG. 5.

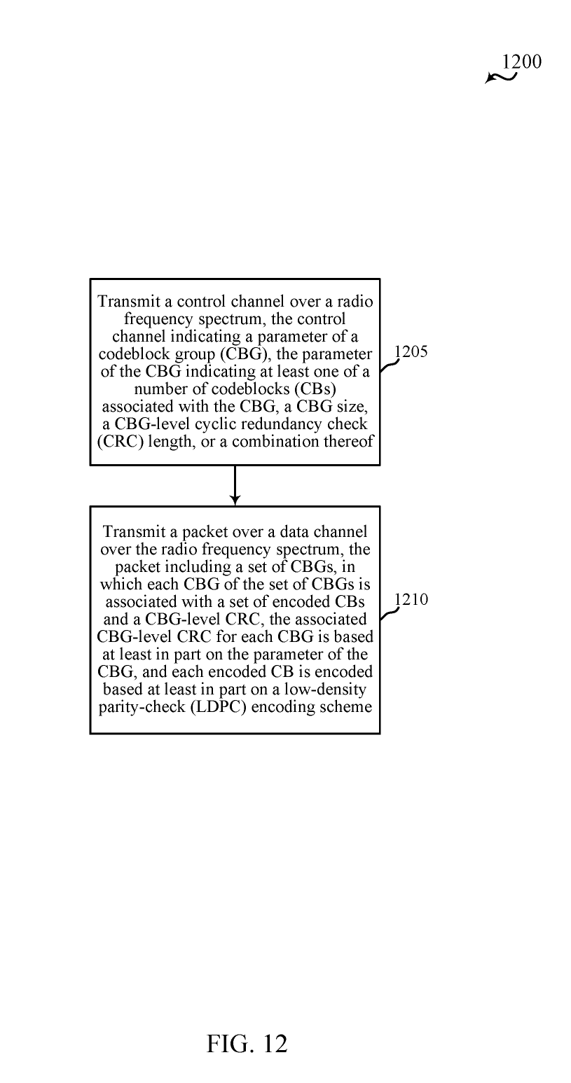

FIG. 12 is a flow chart illustrating an example of a method 1200 for wireless communication at a wireless device, in accordance with various aspects of the present disclosure. For clarity, the method 1200 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 6, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1205, the method 1200 may include transmitting a control channel over a radio frequency spectrum. The control channel may indicate a parameter of a CBG. The parameter of the CBG may indicate at least one of a number of CBs associated with the CBG, a CBG size, a CBG-level CRC length, or a combination thereof. In certain examples, the operation(s) at block 1205 may be performed using the CBG parameter manager 635 or control channel transmission manager 640 described with reference to FIG. 6.

At block 1210, the method 1200 may include transmitting a packet over a data channel over the radio frequency spectrum. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may be encoded based at least in part on a LDPC encoding scheme. In some examples, the packet may include a TB, or a TB with TB-level CRC. In certain examples, the operation(s) at block 1210 may be performed using the data channel transmission manager 645, the LDPC encoding manager 655, or the CBG-level CRC manager 650 described with reference to FIG. 6.

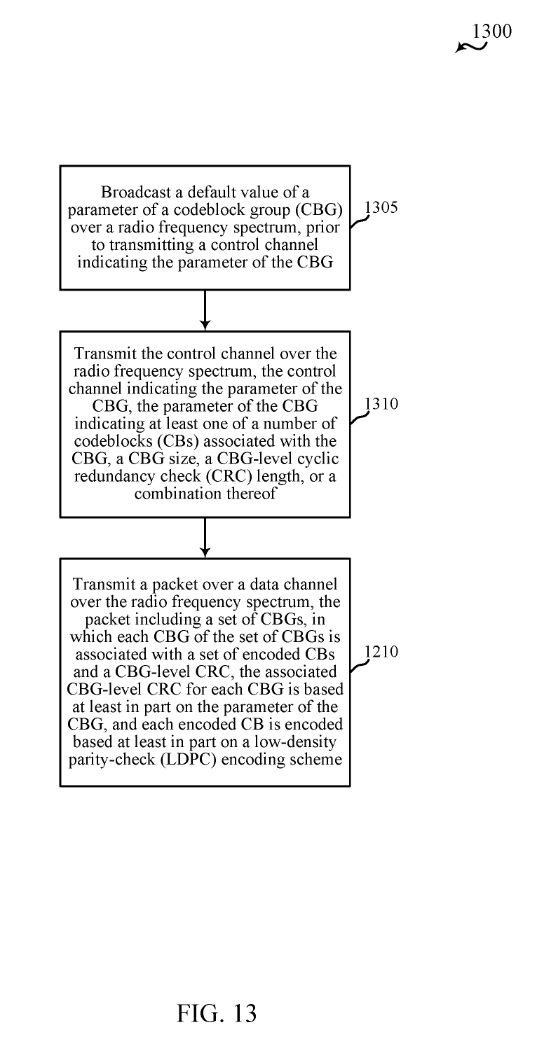

FIG. 13 is a flow chart illustrating an example of a method 1300 for wireless communication at a wireless device, in accordance with various aspects of the present disclosure. For clarity, the method 1300 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 6, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1305, and prior to transmitting a control channel at block 1310, the method 1300 may include broadcasting a default value of a parameter of a CBG over a radio frequency spectrum. The parameter of the CBG may indicate at least one of a number of CBs associated with the CBG, a CBG size, a CBG-level CRC length, or a combination thereof. In certain examples, the operation(s) at block 1305 may be performed using the CBG parameter manager 635 described with reference to FIG. 6.

At block 1310, the method 1300 may include transmitting the control channel over the radio frequency spectrum. The control channel may indicate the parameter of the CBG. The parameter of the CBG may indicate at least one of a number of CBs associated with the CBG, a CBG size, a CBG-level CRC length, or a combination thereof. In some examples, the control channel may indicate the parameter of the CBG by indicating a modification to the default value of the parameter of the CBG. In certain examples, the operation(s) at block 1310 may be performed using the CBG parameter manager 635 or control channel transmission manager 640 described with reference to FIG. 6.

At block 1315, the method 1300 may include transmitting a packet over a data channel over the radio frequency spectrum. The packet may include a set of CBGs. Each CBG of the set of CBGs may be associated with a set of encoded CBs and a CBG-level CRC. The associated CBG-level CRC for each CBG may be based at least in part on the parameter of the CBG. Each encoded CB may be encoded based at least in part on a LDPC encoding scheme. In some examples, the packet may include a TB, or a TB with TB-level CRC. In certain examples, the operation(s) at block 1315 may be performed using the data channel transmission manager 645, the LDPC encoding manager 655, or the CBG-level CRC manager 650 described with reference to FIG. 6.

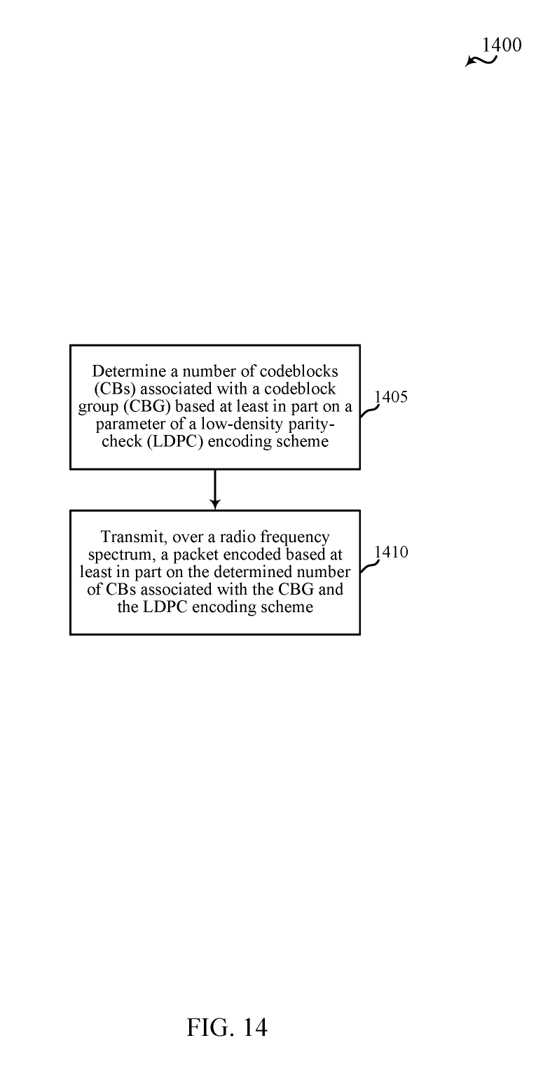

FIG. 14 is a flow chart illustrating an example of a method 1400 for wireless communication at a wireless device, in accordance with various aspects of the present disclosure. For clarity, the method 1400 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 6, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1405, the method 1400 may include determining a number of CBs associated with a CBG based at least in part on a parameter of a LDPC encoding scheme. In some examples, the parameter of the LDPC encoding scheme may include a lifting factor. In some examples, the number of CBs associated with the CBG may also be determined based at least in part on a CBG size restraint. In some examples, the number of CBs associated with the CBG may also be determined based on at least one of a number of MIMO transmission layers on which the packet is transmitted, a number of codewords included in the packet, a CB size, a code rate, or a combination thereof. In certain examples, the operation(s) at block 1405 may be performed using the CBG parameter manager 635 described with reference to FIG. 6.

At block 1410, the method 1400 may include transmitting, over a radio frequency spectrum, a packet encoded based at least in part on the determined number of CBs associated with the CBG and the LDPC encoding scheme. In certain examples, the operation(s) at block 1410 may be performed using the data channel transmission manager 645 or LDPC encoding manager 655 described with reference to FIG. 6.

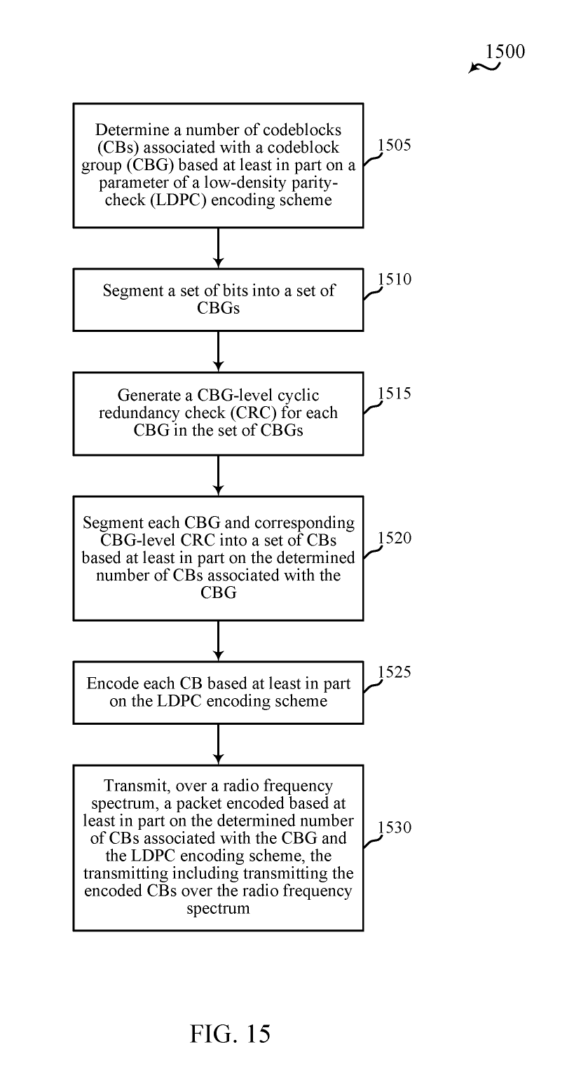

FIG. 15 is a flow chart illustrating an example of a method 1500 for wireless communication at a wireless device, in accordance with various aspects of the present disclosure. For clarity, the method 1500 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 6, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1505, the method 1500 may include determining a number of CBs associated with a CBG based at least in part on a parameter of a LDPC encoding scheme. In some examples, the parameter of the LDPC encoding scheme may include a lifting factor. In some examples, the number of CBs associated with the CBG may also be determined based at least in part on a CBG size restraint. In some examples, the number of CBs associated with the CBG may also be determined based on at least one of a number of MIMO transmission layers on which the packet is transmitted, a number of codewords included in the packet, a CB size, a code rate, or a combination thereof. In certain examples, the operation(s) at block 1505 may be performed using the CBG parameter manager 635 described with reference to FIG. 6.

At block 1510, the method 1500 may include segmenting a set of bits into a set of CBGs. In certain examples, the operation(s) at block 1510 may be performed using the data channel transmission manager 645 described with reference to FIG. 6.

At block 1515, the method 1500 may include generating a CBG-level cyclic redundancy check (CRC) for each CBG in the set of CBGs. In certain examples, the operation(s) at block 1515 may be performed using the data channel transmission manager 645 or CBG-level CRC manager 650 described with reference to FIG. 6.

At block 1520, the method 1500 may include segmenting each CBG and corresponding CBG-level CRC into a set of CBs based at least in part on the determined number of CBs associated with the CBG. In certain examples, the operation(s) at block 1520 may be performed using the data channel transmission manager 645 described with reference to FIG. 6.

At block 1525, the method 1500 may include encoding each CB based at least in part on the LDPC encoding scheme. In certain examples, the operation(s) at block 1525 may be performed using the LDPC encoding manager 655 described with reference to FIG. 6.

At block 1530, the method 1500 may include transmitting, over a radio frequency spectrum, a packet encoded based at least in part on the determined number of CBs associated with the CBG and the LDPC encoding scheme. Transmitting the packet over the radio frequency spectrum may include transmitting the encoded CBs over the radio frequency spectrum. In certain examples, the operation(s) at block 1530 may be performed using the data channel transmission manager 645 or LDPC encoding manager 655 described with reference to FIG. 6.

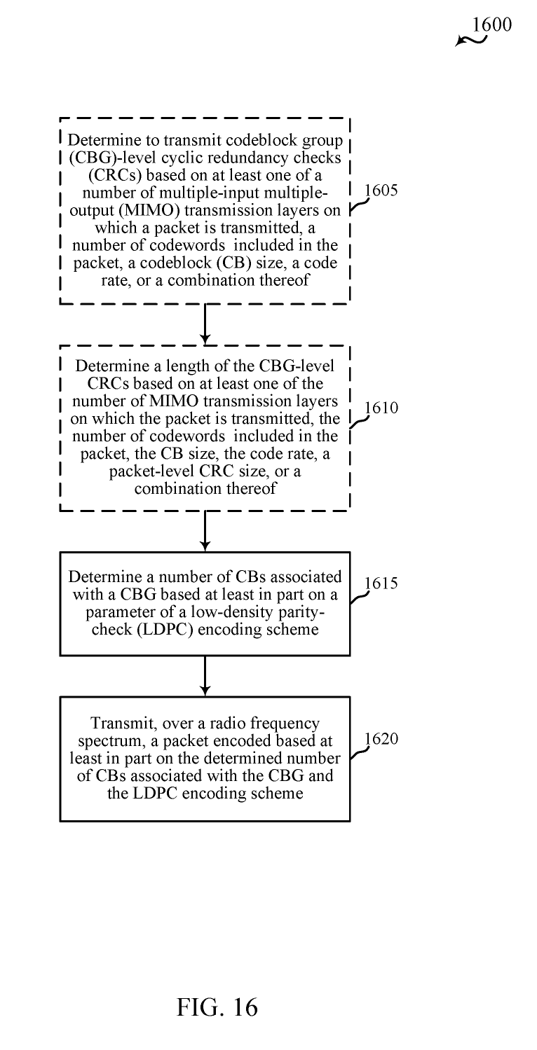

FIG. 16 is a flow chart illustrating an example of a method 1600 for wireless communication at a wireless device, in accordance with various aspects of the present disclosure. For clarity, the method 1600 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 6, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1605, the method 1600 may optionally include determining to transmit CBG-level CRCs based on at least one of a number of MIMO transmission layers on which a packet is transmitted, a number of codewords included in the packet, a CB size, a code rate, or a combination thereof. In certain examples, the operation(s) at block 1605 may be performed using the CBG-level CRC manager 650 described with reference to FIG. 6.

At block 1610, the method 1600 may optionally include determining a length of the CBG-level CRCs based on at least one of the number of MIMO transmission layers on which the packet is transmitted, the number of codewords included in the packet, the CB size, the code rate, a packet-level CRC size (which in some cases be zero, indicating there is no packet-level CRC), or a combination thereof. In certain examples, the operation(s) at block 1610 may be performed using the CBG-level CRC manager 650 described with reference to FIG. 6.

At block 1615, the method 1600 may include determining a number of CBs associated with a CBG based at least in part on a parameter of a LDPC encoding scheme. In some examples, the parameter of the LDPC encoding scheme may include a lifting factor. In some examples, the number of CBs associated with the CBG may also be determined based at least in part on a CBG size restraint. In some examples, the number of CBs associated with the CBG may also be determined based on at least one of the number of MIMO transmission layers on which the packet is transmitted, the number of codewords included in the packet, the CB size, the code rate, or a combination thereof. In certain examples, the operation(s) at block 1615 may be performed using the CBG parameter manager 635 described with reference to FIG. 6.

At block 1620, the method 1600 may include transmitting, over a radio frequency spectrum, a packet encoded based at least in part on the determined number of CBs associated with the CBG and the LDPC encoding scheme. In certain examples, the operation(s) at block 1620 may be performed using the data channel transmission manager 645 or LDPC encoding manager 655 described with reference to FIG. 6.

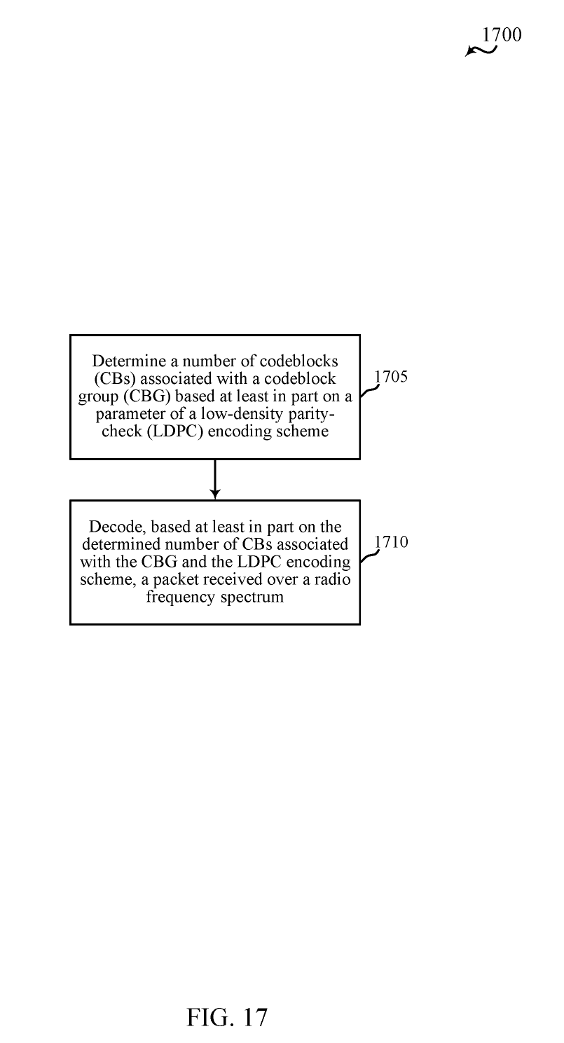

FIG. 17 is a flow chart illustrating an example of a method 1700 for wireless communication at a wireless device, in accordance with various aspects of the present disclosure. For clarity, the method 1700 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 5, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1705, the method 1700 may include determining a number of CBs associated with a CBG based at least in part on a parameter of a LDPC encoding scheme. In some examples, the parameter of the LDPC encoding scheme may include a lifting factor. In some examples, the number of CBs associated with the CBG may also be determined based at least in part on a CBG size restraint. In some examples, the number of CBs associated with the CBG may also be determined based on at least one of a number of MIMO transmission layers on which the packet is received, a number of codewords included in the packet, a CB size, a code rate, or a combination thereof. In certain examples, the operation(s) at block 1705 may be performed using the CBG parameter manager 535 described with reference to FIG. 5.

At block 1710, the method 1700 may include decoding, based at least in part on the determined number of CBs associated with the CBG and the LDPC encoding scheme, a packet received over a radio frequency spectrum. In certain examples, the operation(s) at block 1710 may be performed using the data channel reception manager 545, the LDPC decoding manager 550, or the CBG-level CRC manager 555 described with reference to FIG. 5.

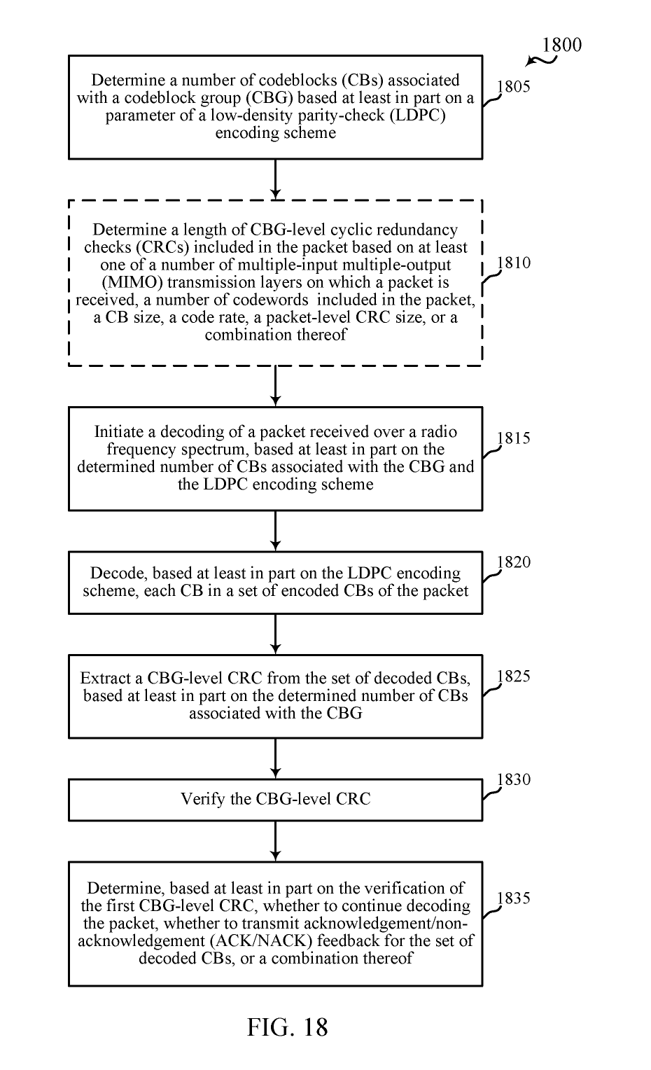

FIG. 18 is a flow chart illustrating an example of a method 1800 for wireless communication at a wireless device, in accordance with various aspects of the present disclosure. For clarity, the method 1800 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 5, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1805, the method 1800 may include determining a number of CBs associated with a CBG based at least in part on a parameter of a LDPC encoding scheme. In some examples, the parameter of the LDPC encoding scheme may include a lifting factor. In some examples, the number of CBs associated with the CBG may also be determined based at least in part on a CBG size restraint. In some examples, the number of CBs associated with the CBG may also be determined based on at least one of a number of MIMO transmission layers on which a packet is received, a number of codewords included in the packet, a CB size, a code rate, or a combination thereof. In certain examples, the operation(s) at block 1805 may be performed using the CBG parameter manager 535 described with reference to FIG. 5.

At block 1810, the method 1800 may optionally include determining a length of CBG-level CRCs included in the packet based on at least one of the number of MIMO transmission layers on which the packet is received, the number of codewords included in the packet, the CB size, the code rate, a packet-level CRC size (which in some cases be zero, indicating there is no packet-level CRC), or a combination thereof. In certain examples, the operation(s) at block 1810 may be performed using the CBG parameter manager 535 described with reference to FIG. 5.

At block 1815, the method 1800 may include initiating the decoding of a packet received over a radio frequency spectrum. The decoding may be based at least in part on the determined number of CBs associated with the CBG and the LDPC encoding scheme. In certain examples, the operation(s) at block 1815 may be performed using the data channel reception manager 545, the LDPC decoding manager 550, or the CBG-level CRC manager 555 described with reference to FIG. 5.

At block 1820, the method 1800 may include decoding, based at least in part on the LDPC encoding scheme, each CB in a set of encoded CBs of the packet. In certain examples, the operation(s) at block 1820 may be performed using the LDPC decoding manager 550 described with reference to FIG. 5.

At block 1825, the method 1800 may include extracting a CBG-level CRC from the set of decoded CBs. The CBG-level CRC may be extracted based at least in part on the determined number of CBs associated with the CBG. In certain examples, the operation(s) at block 1825 may be performed using the CBG-level CRC manager 555 described with reference to FIG. 5.

At block 1830, the method 1800 may include verifying the CBG-level CRC. In certain examples, the operation(s) at block 1830 may be performed using the CBG-level CRC manager 555 described with reference to FIG. 5.

At block 1835, the method 1800 may include determining, based at least in part on the verification of the first CBG-level CRC, whether to continue decoding the packet, whether to transmit acknowledgement/non-acknowledgement (ACK/NACK) feedback for the set of decoded CBs, or a combination thereof. In certain examples, the operation(s) at block 1835 may be performed using the CBG-level CRC manager 555 described with reference to FIG. 5.

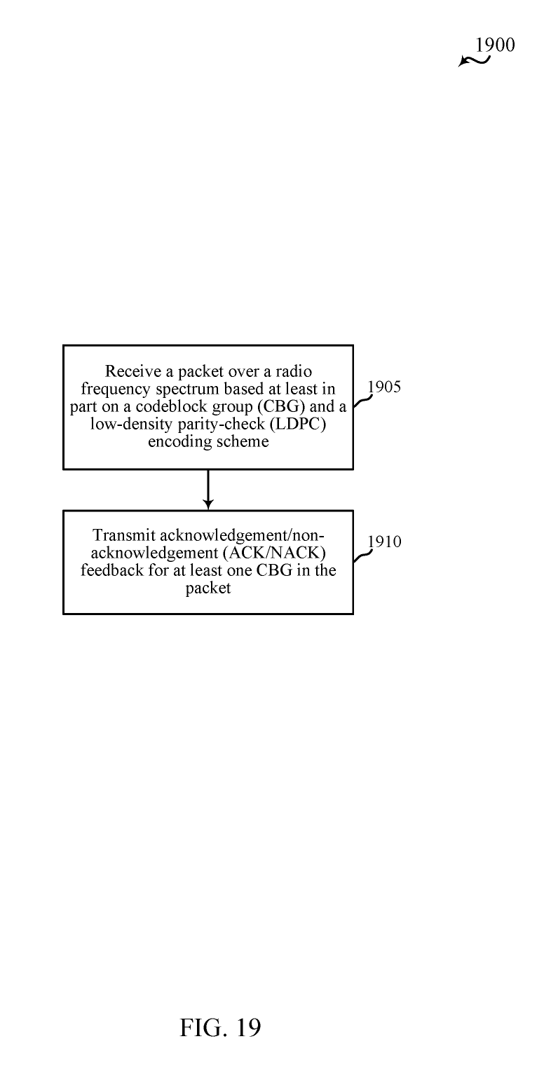

FIG. 19 is a flow chart illustrating an example of a method 1900 for wireless communication at a wireless device, in accordance with various aspects of the present disclosure. For clarity, the method 1900 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 5, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 1905, the method 1900 may include receiving a packet over a radio frequency spectrum based at least in part on a CBG and a LDPC encoding scheme. In certain examples, the operation(s) at block 1905 may be performed using the data channel reception manager 545, the LDPC decoding manager 550, or the CBG-level CRC manager 555 described with reference to FIG. 5.

At block 1910, the method 1900 may include transmitting ACK/NACK feedback for at least one CBG in the packet. In certain examples, the operation(s) at block 1910 may be performed using the ACK/NACK feedback manager 560 described with reference to FIG. 5.

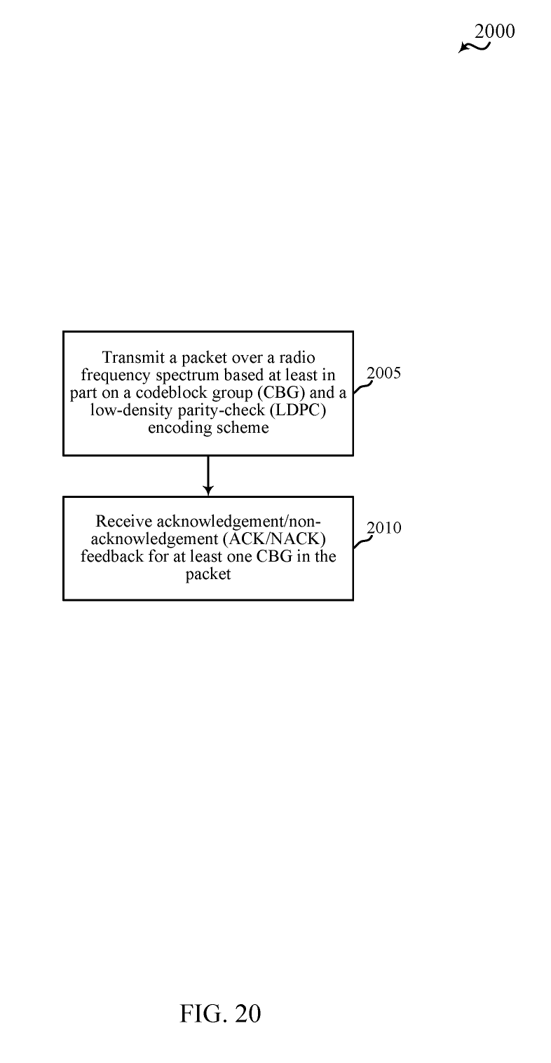

FIG. 20 is a flow chart illustrating an example of a method 2000 for wireless communication at a wireless device, in accordance with various aspects of the present disclosure. For clarity, the method 2000 is described below with reference to aspects of one or more of the wireless devices (e.g., network access devices, UEs, or apparatus) described with reference to FIG. 1, 4, 7, or 8, or aspects of one or more of the wireless communication managers described with reference to FIG. 1, 4, 6, 7, or 8. In some examples, one or more processors of a wireless device may execute one or more sets of codes stored in memory to control the functional elements of the wireless device, including a transceiver, to perform the functions described below. Additionally or alternatively, the wireless device may perform one or more of the functions described below using special-purpose hardware.

At block 2005, the method 2000 may include transmitting a packet over a radio frequency spectrum based at least in part on a CBG and a LDPC encoding scheme. In certain examples, the operation(s) at block 2005 may be performed using the data channel transmission manager 645, the LDPC encoding manager 655, or the CBG-level CRC manager 650 described with reference to FIG. 6.

At block 2010, the method 2000 may include receiving ACK/NACK feedback for at least one CBG in the packet. In certain examples, the operation(s) at block 2010 may be performed using the ACK/NACK feedback manager 660 described with reference to FIG. 6.

The methods 900, 1000, 1100, 1200, 1300, 1400, 1500, 1600, 1700, 1800, 1900, and 2000 described with reference to FIGS. 9, 10, 11, 12, 13, 14, 15, 16, 17, 18, 19, and 20 may provide for wireless communication. It should be noted that the methods 900, 1000, 1100, 1200, 1300, 1400, 1500, 1600, 1700, 1800, 1900, and 2000 are example implementations, and the operations of the methods 900, 1000, 1100, 1200, 1300, 1400, 1500, 1600, 1700, 1800, 1900, and 2000 may be rearranged, combined with other operations of the same or different method, or otherwise modified, such that other implementations are possible. Operations may also be added to the methods 900, 1000, 1100, 1200, 1300, 1400, 1500, 1600, 1700, 1800, 1900, and 2000.

Techniques described herein may be used for various wireless communication systems such as CDMA, TDMA, FDMA, OFDMA, SC-FDMA, and other systems. The terms “system” and “network” are often used interchangeably. A CDMA system may implement a radio technology such as CDMA2000, Universal Terrestrial Radio Access (UTRA), etc. CDMA2000 covers IS-2000, IS-95, and IS-856 standards. IS-2000 Releases 0 and A may be referred to as CDMA2000 1×, 1×, etc. IS-856 (TIA-856) may be referred to as CDMA2000 1×EV-DO, High Rate Packet Data (HRPD), etc. UTRA includes Wideband CDMA (WCDMA) and other variants of CDMA. A TDMA system may implement a radio technology such as Global System for Mobile Communications (GSM). An OFDMA system may implement a radio technology such as Ultra Mobile Broadband (UMB), Evolved UTRA (E-UTRA), IEEE 802.11 (Wi-Fi), IEEE 802.16 (WiMAX), IEEE 802.20, Flash-OFDM™, etc. UTRA and E-UTRA are part of Universal Mobile Telecommunication System (UMTS). 3GPP LTE and LTE-A are new releases of UMTS that use E-UTRA. UTRA, E-UTRA, UMTS, LTE, LTE-A, and GSM are described in documents from an organization named 3GPP. CDMA2000 and UMB are described in documents from an organization named “3rd Generation Partnership Project 2” (3GPP2). The techniques described herein may be used for the systems and radio technologies mentioned above as well as other systems and radio technologies, including cellular (e.g., LTE) communications over an unlicensed or shared bandwidth. The description above, however, describes an LTE/LTE-A system for purposes of example, and LTE terminology is used in much of the description above, although the techniques are applicable beyond LTE/LTE-A applications.

The detailed description set forth above in connection with the appended drawings describes examples and does not represent all of the examples that may be implemented or that are within the scope of the claims. The terms “example” and “exemplary,” when used in this description, mean “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and apparatuses are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative blocks and components described in connection with the disclosure herein may be implemented or performed with a general-purpose processor, a digital signal processor (DSP), an ASIC, an FPGA or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope and spirit of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. As used herein, including in the claims, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination. Also, as used herein, including in the claims, “or” as used in a list of items (for example, a list of items prefaced by a phrase such as “at least one of” or “one or more of”) indicates a disjunctive list such that, for example, a list of “at least one of A, B, or C” means A or B or C or AB or AC or BC or ABC (i.e., A and B and C).

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” “component,” and the like may not be a substitute for the word “means.” As such, no claim element is to be construed as a means plus function unless the element is expressly recited using the phrase “means for.”

Computer-readable media includes both computer storage media and communication media including any medium that facilitates transfer of a computer program from one place to another. A storage medium may be any available medium that can be accessed by a general purpose or special purpose computer. By way of example, and not limitation, computer-readable media can comprise RAM, ROM, EEPROM, flash memory, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not to be limited to the examples and designs described herein but is to be accorded the broadest scope consistent with the principles and novel techniques disclosed herein.

What is claimed is:

1. A method for wireless communication at a wireless device, comprising:
receiving a control channel and a data channel over a radio frequency spectrum;
decoding the control channel, the control channel indicating a parameter of a codeblock group (CBG), the parameter of the CBG indicating at least one of a number of codeblocks (CBs) associated with the CBG, a CBG size, or a combination thereof; and
decoding a packet received over the data channel, the packet including a set of CBGs, wherein each CBG of the set of CBGs is associated with a set of encoded CBs, and each encoded CB was encoded based at least in part on a low-density parity-check (LDPC) encoding scheme.

2. The method of claim 1, wherein:
each CBG of the set of CBGs is associated with a CBG level cyclic redundancy check (CRC) based at least in part on the parameter of the CBG.

3. The method of claim 1, further comprising:
prior to decoding the control channel, decoding a transmission received over the radio frequency spectrum based at least in part on a default value of the parameter of the CBG.

4. The method of claim 3, further comprising:
obtaining the default value of the parameter of the CBG from a broadcast channel received over the radio frequency spectrum, or from configuration information stored at the wireless device.

5. The method of claim 4, wherein the control channel indicates the parameter of the CBG by indicating a modification to the default value of the parameter of the CBG.

6. The method of claim 1, further comprising:
decoding each CB in a set of encoded CBs based at least in part on the LDPC encoding scheme; and
determining whether to transmit acknowledgement/non-acknowledgement (ACK/NACK) feedback for the set of decoded CBs.

7. The method of claim 1, wherein decoding the packet comprises decoding each encoded CB in a set of encoded CBs based at least in part on the LDPC encoding scheme, the method further comprising:
extracting from the set of decoded CBs, based at least in part on the parameter of the CBG, a first CBG-level CRC;
verifying the first CBG-level CRC; and
determining, based at least in part on the verification of the first CBG-level CRC, whether to continue decoding the packet, whether to transmit acknowledgement/non-acknowledgement (ACK/NACK) feedback for the set of decoded CBs, or a combination thereof.

8. The method of claim 1, wherein the packet comprises a transport block (TB) or a TB with a TB-level CRC.

9. An apparatus for wireless communication at a wireless device, comprising:
a transceiver;
a processor;
memory in electronic communication with the processor; and
instructions stored in the memory, the instructions being executable by the processor to implement a wireless communication manager configured to:
receive, via the transceiver, a control channel and a data channel over a radio frequency spectrum;
decode the control channel, the control channel indicating a parameter of a codeblock group (CBG), the parameter of the CBG indicating at least one of a number of codeblocks (CBs) associated with the CBG, a CBG size, or a combination thereof; and
decode a packet received over the data channel, the packet including a set of CBGs, wherein each CBG of the set of CBGs is associated with a set of encoded CBs, and each encoded CB was encoded based at least in part on a low-density parity-check (LDPC) encoding scheme.

10. The apparatus of claim 9, wherein:
each CBG of the set of CBGs is associated with a CBG level cyclic redundancy check (CRC) based at least in part on the parameter of the CBG.

11. The apparatus of claim 9, wherein the instructions are further executable by the processor to implement the wireless communications manager configured to:
prior to decoding the control channel, decoding a transmission received over the radio frequency spectrum based at least in part on a default value of the parameter of the CBG.

12. The apparatus of claim 11, wherein the instructions are further executable by the processor to implement the wireless communications manager configured to:
obtain the default value of the parameter of the CBG from a broadcast channel received over the radio frequency spectrum, or from configuration information stored at the wireless device.

13. The apparatus of claim 12, wherein:
the control channel indicates the parameter of the CBG by indicating a modification to the default value of the parameter of the CBG.

14. The apparatus of claim 9, wherein the instructions are further executable by the processor to implement the wireless communications manager configured to:
decode each CB in a set of encoded CBs based at least in part on the LDPC encoding scheme; and
determine whether to transmit acknowledgement/non-acknowledgement (ACK/NACK) feedback for the set of decoded CBs.

15. The apparatus of claim 9, wherein decoding the packet comprises decoding each encoded CB in a set of encoded CBs based at least in part on the LDPC encoding scheme, and wherein the instructions are further executable by the processor to:
extract from the set of decoded CBs, based at least in part on the parameter of the CBG, a first CBG-level cyclic redundancy check (CRC);
verifying the first CBG-level CRC; and
determining, based at least in part on the verification of the first CBG-level CRC, whether to continue decoding the packet, whether to transmit acknowledgement/non-acknowledgement (ACK/NACK) feedback for the set of decoded CBs, or a combination thereof.

16. The apparatus of claim 9, wherein the packet comprises a transport block (TB) or a TB with a TB-level cyclic redundancy check.

17. A method for wireless communication at a wireless device, comprising:
receiving a packet over a radio frequency spectrum based at least in part on a codeblock group (CBG) and a low-density parity-check (LDPC) encoding scheme; and
transmitting acknowledgement/non-acknowledgement (ACK/NACK) feedback for at least one CBG in the packet.

18. The method of claim 17, further comprising:
transmitting ACK/NACK feedback for each CBG in the packet.

19. The method of claim 17, wherein:
the CBG comprises a set of codeblocks (CBs) less than a total number of CBs in the packet.

20. The method of claim 17, further comprising:
determining a cyclic redundancy check (CRC) value for the CBG;
verifying the CRC value; and
generating the ACK/NACK feedback based at least in part on the verification of the CRC value.

21. The method of claim 17, wherein:
the CBG comprises a single codeblock (CB).

22. The method of claim 21, further comprising:
determining a cyclic redundancy check (CRC) value for the CB;
verifying the CRC value; and
generating the ACK/NACK feedback based at least in part on the verification of the CRC value.

23. The method of claim 17, further comprising:
receiving a retransmission of the CBG based at least in part on the ACK/NACK feedback.

24. An apparatus for wireless communication at a wireless device, comprising:
a transceiver;
a processor;
memory in electronic communication with the processor; and
instructions stored in the memory, the instructions being executable by the processor to implement a wireless communications manager configured to:
receive, via the transceiver, a packet over a radio frequency spectrum based at least in part on a codeblock group (CBG) and a low-density parity-check (LDPC) encoding scheme; and
transmit acknowledgement/non-acknowledgement (ACK/NACK) feedback for at least one CBG in the packet.

25. The apparatus of claim 24, wherein the instructions are further executable by the processor to implement the wireless communications manager configured to:
transmit ACK/NACK feedback for each CBG in the packet.

26. The apparatus of claim 24, wherein:
the CBG comprises a set of codeblocks (CBs) less than a total number of CBs in the packet.

27. The apparatus of claim 24, wherein the instructions are further executable by the processor to implement the wireless communications manager configured to:
determine a cyclic redundancy check (CRC) value for the CBG;
verify the CRC value; and
generate the ACK/NACK feedback based at least in part on the verification of the CRC value.

28. The apparatus of claim 24, wherein:
the CBG comprises a single codeblock (CB).

29. The apparatus of claim 24, wherein the instructions are further executable by the processor to implement the wireless communications manager configured to:
determine a cyclic redundancy check (CRC) value for the CB;
verify the CRC value; and
generate the ACK/NACK feedback based at least in part on the verification of the CRC value.

30. The apparatus of claim 24, wherein the instructions are further executable by the processor to implement the wireless communications manager configured to:
receive a retransmission of the CBG based at least in part on the ACK/NACK feedback.
